(19) United States
(12) Patent Application Publication
(10) Pub. No.: US 2011/0226335 A1
(43) Pub. Date: Sep. 22, 2011

(54) SOLAR CELL MODULE

(76) Inventors: Katsuyuki Naitoh, Osaka (JP); Ryutarou Watanabe, Osaka (JP)

(21) Appl. No.: 13/131,704

(22) PCT Filed: Nov. 26, 2009
(86) PCT No.: PCT/JP2009/069931

§ 371 Date: May 27, 2011

(30) Foreign Application Priority Data
Nov. 27, 2008 (JP) 2008-302945
Nov. 27, 2008 (JP) 2008-302946

(51) Int. Cl. H01L 31/0203

(52) U.S. Cl. 136/259

(57) ABSTRACT

In a solar cell module (1) according to an embodiment of the present invention, a reinforcement member (30) is bonded to a back film (87) of a solar cell panel (2) by an adhesive member (40) serving as an adhesive layer. The adhesive member (40) is interposed between the back film (87) and the reinforcement member (30) so as to protrude from a peripheral edge portion of an upper horizontal plate (31) of the reinforcement member (30). The distance between the peripheral edge portion of the upper horizontal plate (31) of the reinforcement member (30) and the back film (87) can thereby be increased and maintained, and insulation between the reinforcement member (30) and an Al layer included in the back film (87) can be increased.

### TECHNICAL FIELD

The present invention relates to a solar cell module having a structure in which one or more reinforcement members are bonded to a solar cell panel using an adhesive member.

### BACKGROUND ART

With the increase in panel area, it has become common to fit a conventional solar cell module such as a thin film-type solar cell module into a frame body so as to give mechanical strength and weather resistance before use. In this case, in order to maintain the strength of the solar cell module, techniques, such as increasing the thickness of the frame body, increasing the thickness of panel constituting members and using special tempered glass, are being used, but they are problematic in that the overall weight and the cost of the constituent members are increased. Also, when the thickness of the surface substrate (light-transmitting resin substrate) of the solar cell module is increased in order to give a sufficient strength, problems arise such as reduced photoelectric conversion efficiency due to decreased amount of incident light.

In view of the above, in order to solve the problems, techniques for maintaining the mechanical strength of a solar cell module without substantially increasing the thickness of the constituent members of the solar cell module have been conventionally proposed (see, for example, Patent Document 1).

FIG. 22 is a perspective view showing an example overall configuration of a conventional solar cell module as described above, and FIG. 23 is a cross-sectional view taken along the line E-E shown in FIG. 22. FIG. 22 is a perspective view when the solar cell panel is viewed from the back face (in other words, the side opposite to the light-receiving face).

A conventional solar cell module 100 is constituted by a solar cell panel 110, a rectangular frame member (frame body) 120 that holds the periphery of the solar cell panel 110, and a reinforcement member 130 having end portions that are fixed to the frame member 120. The reinforcement member 130 is formed in a lateral H shape composed of an upper piece 131 that abuts the solar cell panel 110, a lower piece 132 having end portions that abut bottom pieces 121 of the frame member 120 and a support piece 133 that couples the upper piece 131 and the lower piece 132. The upper piece 131 of the reinforcement member 130 and the back face of the solar cell panel 110 are adhesively fixed by an adhesive 140. End portions 132a of the lower piece 132 of the reinforcement member 130 are fixed to the bottom pieces 121 using screws 134. In other words, the reinforcement member 30 has a structure that supports the solar cell panel 110 from below by the end portions 132a of the lower piece 132 being fixed to the bottom pieces 121 of the frame member 120 using the screws 134.

As described above, the conventional solar cell module 100 is configured to prevent deflection of the solar cell module by providing the reinforcement member 130, without substantially increasing the thickness of the constituent members of the solar cell module 100.

### Prior Art Document

### Patent Document

Patent Document 1: JP H10-294485 A

### SUMMARY OF INVENTION

### Problems to be Solved by the Invention

In the solar cell module 100 having the structure described above, the load of the solar cell panel 110 received by the entire upper piece 131 is concentratedly applied to the support piece 133 of the reinforcement member 130. Accordingly, the load is concentratedly applied to the coupling portion 132a of the lower piece 132 coupling to the support piece 133, creating a problem in terms of the strength of the coupling portion.

Also, in the solar cell module having the structure described above, a back film 111 which is a back face protective sheet disposed on the back face of the solar cell module 100 has, for example, a three-layer structure of PET/Al/PET (PET: polyethylene terephthalate) in order to ensure a moisture resistance. More specifically, PET alone cannot prevent water vapor from entering although it can prevent attached water droplets from entering, and therefore an Al layer 111a which is a metal layer (waterproof layer) capable of preventing water vapor from entering is incorporated in the film. Accordingly, as shown in FIG. 23, an upper surface 131 of the reinforcement member 130 and the Al layer 111a of the back film 111 are disposed in extremely close proximity to each other.

The reinforcement member 130 bonded to the back face of the solar cell panel 110 described above is made of a metal material such as aluminum in order to ensure strength. Accordingly, there is a possibility of occurrence of an electrical discharge between the reinforcement member 130 and the Al layer 111a of the back film 111, and it is therefore necessary to increase insulation between the reinforcement member 130 and the Al layer 111a of the back film 111. In this case, when silicone resin is used as the adhesive 140, the silicone resin functions as an insulating material, but if the insulation is insufficient, there is a possibility of occurrence of an electrical surface discharge in, for example, an impulse voltage test assuming a lightning surge.

An electrical discharge is likely to occur in a sharpened portion, if any, in the reinforcement member 130. Specifically, in the H-shaped reinforcement member 130 described above, an angled edge formed by three faces, namely, the upper surface 135 of the upper piece 131 of the reinforcement member 130 and two adjacent side faces connected to the upper surface 135, intersecting is the sharpest portion, and thus an electrical discharge is most likely to occur between the angled edge and the Al layer 111a of the back film 111. An electrical discharge is also highly likely to occur between the Al layer 111a of the back film 111 and an angular portion 138 formed by the upper surface 135 and a side face 136 of the upper piece 131 connected at the right angle. Furthermore, an electrical discharge may also occur between the Al layer 111a of the back film 111 and each side face 136 of the upper piece 131 of the reinforcement member 130 that is not covered by the adhesive 140, if the distance between the Al layer 111a and the side face 136 is short.

Patent Document 1 described above also states that the reinforcement member 130 may have a hollow cylindrical configuration instead of the H-shaped configuration. FIG. 24 shows a cross-sectional shape in the case where a hollow cylindrical configuration is used. In a hollow cylindrical reinforcement member 130A, it seems there is no angular portion, but there is the risk of an electrical discharge in a top 130A1 of the arc close to the back film 111 (actually, a straight line in a direction perpendicular to the plane of the drawing sheet, including the top).

The hollow cylindrical reinforcement member 130A also has a problem in that, in order to adhesively fix the reinforcement member 130A to the back film 111 using the adhesive 140 with reliability, it is necessary to mound silicone resin serving as an adhesive on the right and left sides of the top 130A1 so as to fill the space to conform to the arc of the outer circumference of the reinforcement member 130A, wasting a large amount of resin.

Furthermore, the thinner silicone resin is applied, the shorter the curing time, contributing to bonding, but when silicone resin is mounded as described above, a problem will arise such as the resin will not cure easily and thus a long time is required to cure completely, or the resin will not cure completely and thus sufficient adhesion cannot be obtained. Furthermore, the hollow cylindrical reinforcement member 130A has another problem: if the reinforcement member 130A is pressed firmly against the back film 111 when the reinforcement member 130A is bonded to the back film 111, there is a possibility that the top 130A1 of the arc might come into contact with the back film 111, and if such a situation occurs, the insulation function of the adhesive 140 will not work at all, increasing the risk of an electrical discharge.

The present invention has been conceived to solve the problems described above, and the present invention provides a solar cell module in which the solar cell module is reinforced without increasing the thickness of the solar cell module by providing a reinforcement member having a sufficient strength, and an insulation effect between the reinforcement member and a metal layer incorporated in a back face protective sheet is enhanced.

### Means for Solving the Problems

In order to solve the above problems, the solar cell module according to the present invention is a solar cell module that is reinforced by bonding a solar cell panel and a conductive metallic reinforcement member using an adhesive member, the solar cell module including a means for preventing an electrical discharge generated due to a relationship between a conductive member included in the solar cell panel and the reinforcement member.

Specifically, a solar cell module according to the present invention includes a solar cell panel in which a substrate, a solar cell, a sealant and a back face protective sheet are sequentially laminated, and is configured such that at least one reinforcement member is bonded to the back face protective sheet via an adhesive layer and the adhesive layer prevents an electrical surface discharge between the reinforcement member and the back face protective sheet.

More specifically, the reinforcement member is disposed underneath the solar cell panel supported and fixed within a rectangular frame member and is disposed between opposing frame members. The reinforcement member includes an upper piece that is bonded to the back face protective sheet via the adhesive layer, a lower piece having end portions that abut bottom pieces of the frame members and a support piece that couples the upper piece and the lower piece. The lower piece including, underneath, a reinforcing rib piece along an axis direction of the reinforcement member. The adhesive layer is formed so as to protrude from the peripheral edge portion of the upper piece and prevents an electrical surface discharge between the reinforcement member and the back face protective sheet.

With this configuration, because the adhesive layer is provided so as to protrude from the upper piece, the distance between the edge portion of the reinforcement member and the back face protective sheet can be increased and maintained, and insulation between the reinforcement member and a metal layer included in the back face protective sheet can be increased.

In the solar cell module configured as described above, the adhesive layer includes an adhesive member having adhesion properties and is provided between the upper piece and the back face protective sheet. Also, it is preferable that the adhesive member is provided so as to protrude from the peripheral edge portion of the upper piece. With this configuration, the adhesive member increases the distance between the reinforcement member and the back face protective sheet, and therefore insulation between the reinforcement member and the metal layer of the back face protective sheet can be increased.

Also, in the solar cell module of the present invention, the adhesive layer may further include an insulation member having electrical insulation properties and prevent an electrical surface discharge between the reinforcement member and the back face protective sheet.

In this case, it is preferable that in the adhesive layer, the adhesive member is provided inside in a width direction of the adhesive layer, the insulation member is attached to each side edge portion of the adhesive member, and the insulation member is provided so as to protrude from a peripheral edge portion of the upper piece. With this configuration, the insulation member protruding from the peripheral edge portion of the upper piece increases and maintains the distance between the edge portion of the reinforcement member and the back face protective sheet, and thus insulation between the reinforcement member and the metal layer of the back face protective sheet can be increased.

Also, in the adhesive layer, the adhesive member may be attached so as to overlap the insulation member. With this configuration as well, the insulation member protruding from the peripheral edge portion of the upper piece can further increase and maintain the distance between the edge portion of the reinforcement member and the back face protective sheet, and therefore adhesion properties as an adhesive layer, as well as insulation between the reinforcement member and the metal layer of the back face protective sheet can be increased.

Also, in the present invention, it is preferable that in the adhesive member, a surface of an exposed portion protruding from the peripheral edge portion of the reinforcement member is made non-sticky. Furthermore, when the adhesive layer includes the insulation member, it is preferable that a surface of an exposed portion of the insulation member protruding from the peripheral edge portion of the reinforcement member is made non-sticky. By making the exposed portion of the adhesive member or insulation member non-sticky in this manner, it is possible to prevent unwanted conductive matter and the like from being attached to the exposed portion, and therefore the insulation properties can be increased.

Furthermore, in the above configuration, the upper piece of the reinforcement member may have a peripheral edge portion that is bent and separated from the adhesive layer. The distance between the edge portion of the reinforcement member and the back face protective sheet can thereby be made longer in the lateral direction, and the distance in the height direction can also be made longer. Accordingly, insulation between the reinforcement member and the metal layer of the back face protective sheet can be further increased.

Also, the solar cell module of the present invention includes an anti-deformation portion that prevents deformation of the reinforcement member by reinforcing the solar cell panel using the reinforcement member.

Specifically, the reinforcement member of the solar cell module of the present invention includes, as described above, a reinforcing rib piece. The reinforcing rib piece is provided to the lower piece so as to extend along a coupling portion of the support piece of the reinforcement member. Furthermore, the reinforcing rib piece provided along the coupling portion of the support piece may be formed in a protruding shape having a thickness greater than a thickness of other portions of the support piece. By forming the reinforcing rib piece along the coupling portion of the support piece where the most load is applied in this manner, even when the load of the solar cell panel received by the entire upper piece is concentratedly applied to the support piece, the lower piece can be prevented from being deformed, and the load can be sufficiently received by the lower piece.

Also, in the reinforcement member, the reinforcing rib piece may be provided to each edge portion of the lower piece. By forming the reinforcing rib pieces in this manner, it is possible to prevent deformation such as torsion in the lower piece, and strength can be further increased.

Also, a screw hole for screwing the support piece to the bottom pieces of the frame members is formed in an end portion of the lower piece. The screw hole is formed between the reinforcing rib pieces. By providing a screw hole between the reinforcing rib pieces, the screwhead of the inserted screw is embedded between the reinforcing rib pieces, and therefore the screwhead will not interfere with the subsequent operations.

Also, the screw hole may be formed on the reinforcing rib piece facing the coupling portion of the support piece. Specifically, a portion in which the screw hole is to be formed of the reinforcing rib piece is removed, and the screw hole is formed in the removed portion. By forming the screw hole on the reinforcing rib piece facing the coupling portion of the support piece in this manner, the portion where the most load is applied can be screw fixed to the frame member. In other words, only vertical loads will be applied directly to the screw fixing portion and deforming loads such as flexural stress will not be applied, and therefore the reinforcement member will not be deformed, and the solar cell panel can be rigidly supported.

### EFFECTS OF THE INVENTION

According to the present invention, it is possible to reinforce a solar cell module without increasing the thickness of the solar cell module by providing a reinforcement member that ensures a sufficient strength and to enhance an insulation effect between the reinforcement member and a metal layer incorporated in a back face protective sheet.

In other words, insulation between the back face protective sheet of the solar cell panel and the reinforcement member can be increased by the adhesive member, and it is therefore possible to prevent an electrical discharge between the reinforcement member and a metal layer (Al layer) included in the back face protective sheet. Also, according to the present invention, a reinforcing rib piece is formed on the lower piece of the reinforcement member so as to extend along the coupling portion of the support piece, and thus even when the load of the solar cell panel received by the entire upper piece is concentratedly applied to the support piece, the lower piece can be prevented from being deformed, and the load can be sufficiently received by the lower piece.

Also, because the reinforcing rib piece is formed on the lower piece of the reinforcement member so as to extend along the coupling portion of the support piece, even when the load of the solar cell panel received by the entire upper piece is concentratedly applied to the support piece, the lower piece can be prevented from being deformed, and the load can be sufficiently received by the lower piece.

### BRIEF DESCRIPTION OF DRAWINGS

FIG. 1 is a perspective view showing an overall configuration of a solar cell module according to an embodiment of the present invention.

FIG. 2 is a plan view of the solar cell module according to the embodiment of the present invention.

FIG. 3 is a bottom plan view of the solar cell module according to the embodiment of the present invention.

FIG. 4 is an enlarged exploded perspective view of a portion A shown in FIG. 1.

FIG. 5 is a cross-sectional view taken along the line B-B shown in FIG. 1.

FIG. 6 is a cross-sectional view of an end portion of a solar cell panel.

FIG. 7 is an exploded diagram of the longer side frame member and the shorter side frame member shown in the cross-sectional view of FIG. 5.

FIG. 8(a) is an enlarged perspective view of an end portion of a reinforcement member, and FIG. 8(b) is a side view of the same.

FIG. 9 are illustrative diagrams showing specific examples of screw hole formation positions formed in an upper horizontal plate of the reinforcement member.

FIG. 10 are illustrative diagrams showing a procedure for attaching a reinforcement member between longer side frame members.

FIG. 11 are illustrative diagrams showing a procedure for attaching a reinforcement member between longer side frame members.

FIG. 12 is a cross-sectional view taken along the line C-C shown in FIG. 1.

FIG. 13A is a cross-sectional view taken along the line D-D shown in FIG. 1 and corresponds to Specific Example 1.

FIG. 13B is a cross-sectional view showing another specific example of FIG. 13A.

FIG. 13C is a cross-sectional view showing still another specific example of FIG. 13A.

FIG. 14 is a cross-sectional view taken along the line D-D shown in FIG. 1 and corresponds to Specific Example 2.

FIG. 15 is an enlarged perspective view of an end portion of a reinforcement member.

FIG. 16 is a cross-sectional view taken along the line C-C shown in FIG. 1, and corresponds to Specific Example 3.

FIG. 17 is a cross-sectional view taken along the line D-D shown in FIG. 1, and corresponds to Specific Example 3.

FIG. 18(a) is a partially enlarged cross-sectional view showing Specific Example 3-2 of another chamfered shape of the angular portion of the reinforcement member, FIG. 18(b) is a partially enlarged cross-sectional view showing Specific Example 3-3 of another chamfered shape of the angular portion of the reinforcement member, and FIG. 18(c) is a partially enlarged cross-sectional view showing Specific Example 3-4 of another chamfered shape of the angular portion of the reinforcement member.

FIG. 19 is a partially enlarged perspective view showing Specific Example 3-5 of another chamfered shape of the angular portion of the reinforcement member.

FIG. 20 is an illustrative diagram showing a state in which an adhesive is ejected to a reinforcement member by an adhesive ejection apparatus.

FIG. 21 is an exploded perspective view showing frame members of another configuration.

FIG. 22 is a perspective view showing an example overall configuration of a conventional solar cell module.

FIG. 23 is a cross-sectional view taken along the line E-E shown in FIG. 22.

FIG. 24 is a partially enlarged cross-sectional view of a conventional solar cell module in which the reinforcement member has a hollow cylindrical shape.

### MODES FOR CARRYING OUT THE INVENTION

A solar cell module according to an embodiment of the present invention will be described next with reference to the drawings.

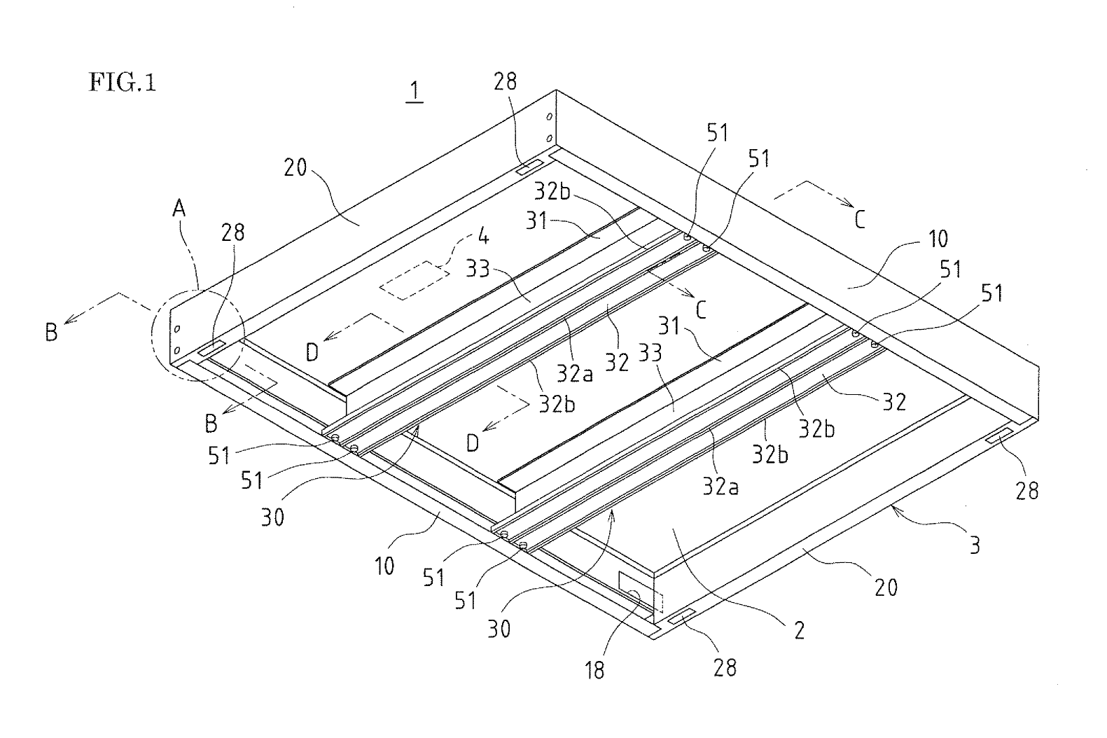

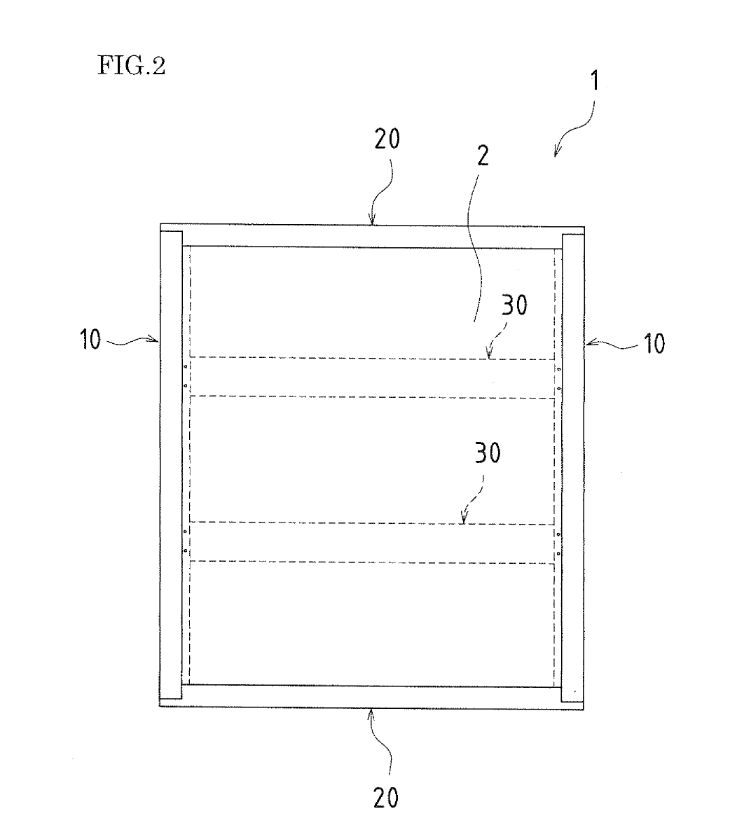

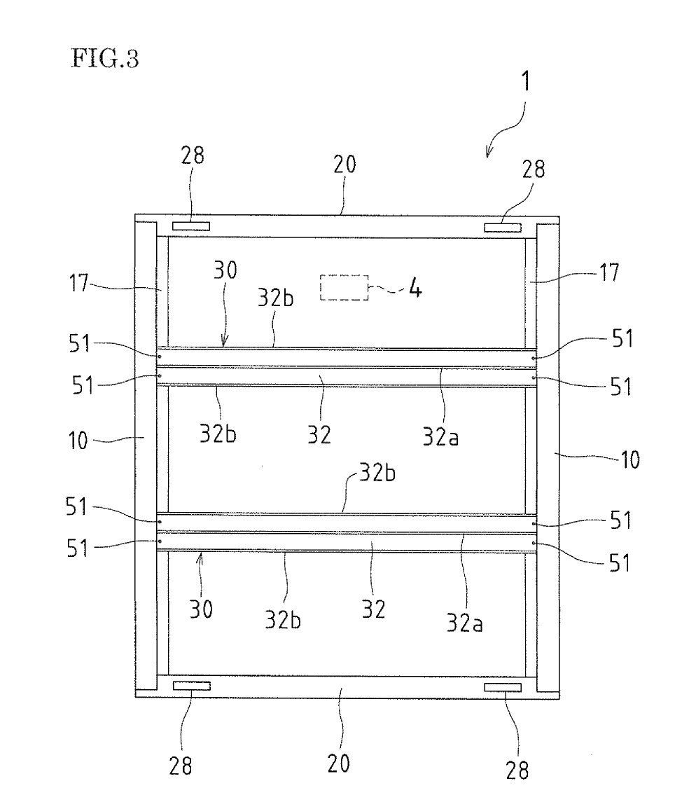

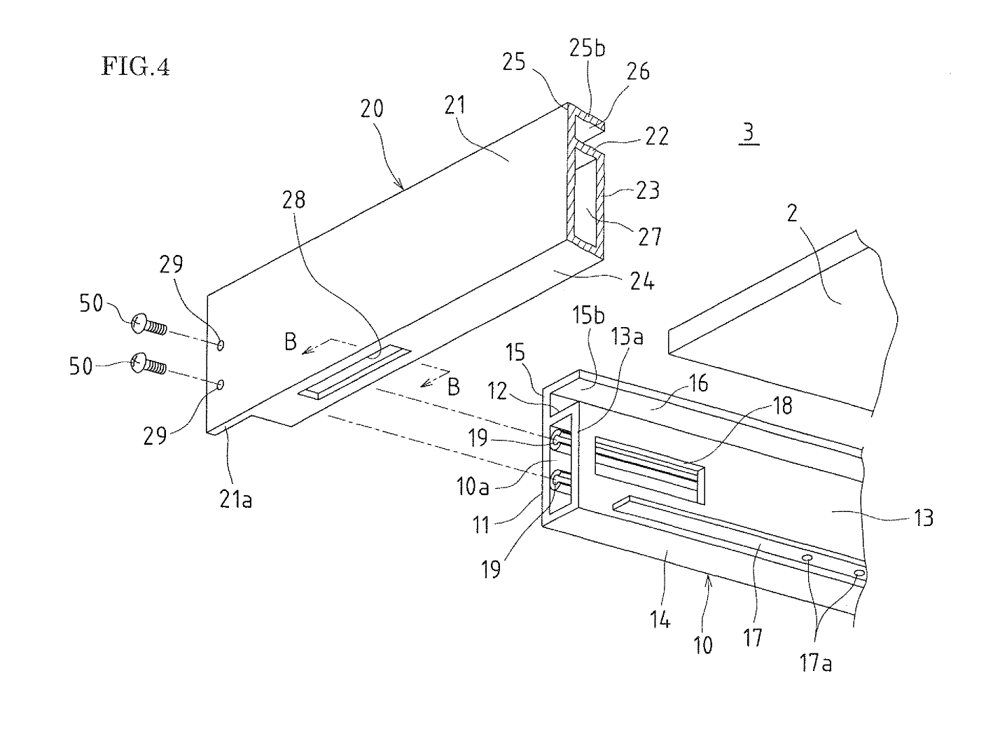

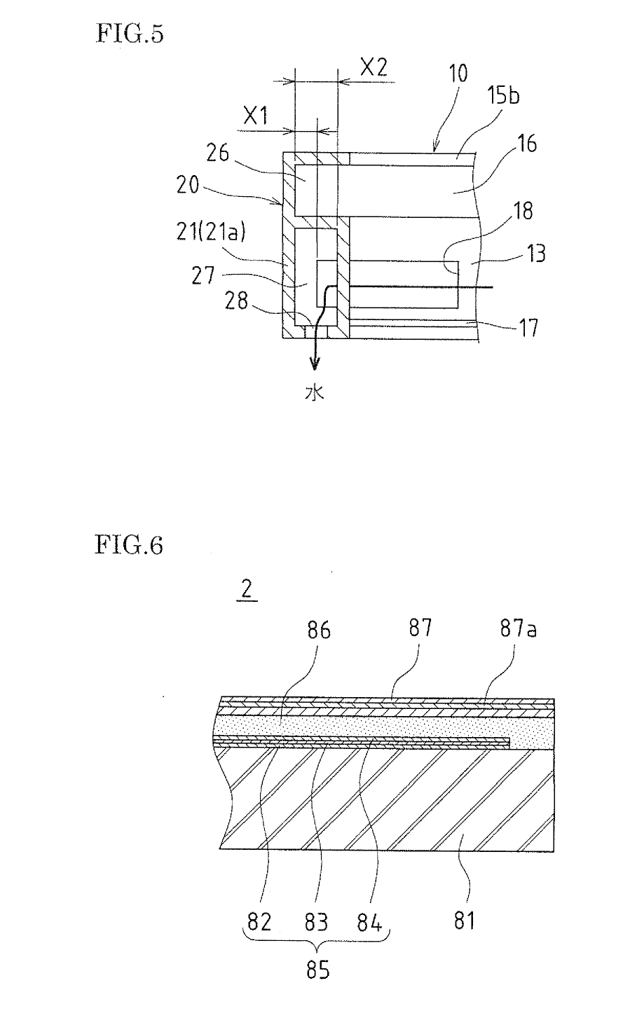

FIG. 1 is a perspective view showing an overall configuration of a solar cell module 1 according to the present embodiment. FIG. 1 is a view as viewed from the back face of the solar cell module 1, or in other words, from the side opposite to the light-receiving face. FIG. 2 is a plan view of the solar cell module 1, and FIG. 3 is a bottom plan view of the same. FIG. 4 is an exploded perspective view of a portion A shown in FIG. 1, and FIG. 5 is a cross-sectional view taken along the line B-B shown in FIG. 1. FIG. 6 is a cross-sectional view of an end portion of a solar cell panel 2.

As shown in FIGS. 1 to 6, the solar cell module 1 of the present embodiment is constituted primarily by an elongated rectangular solar cell panel 2 and a frame member 3 for holding the periphery of the solar cell panel 2. The frame member 3 is constituted by a pair of longer side frame members 10 for holding edge portions in the lengthwise direction (longer side direction) of the solar cell panel 2 and a pair of shorter side frame members 20 for holding edge portions in the lateral direction (shorter side direction) of the solar cell panel 2. The solar cell panel 2 of the present embodiment has external dimensions of approximately 1400 mm×1000 mm. As shown in FIGS. 1 and 3, the back face of the solar cell panel 2 is provided with an output terminal box 4 (indicated by a dotted line) through which output from the solar cell panel 2 is extracted.

As shown in FIG. 6 showing a partially enlarged cross-sectional view of an end portion of the solar cell panel 2, the solar cell panel 2 has an unitary structure in which a transparent electrode film 82 made of a transparent conductive film, a photoelectric conversion layer 83, a back face electrode film 84 that constitute a solar cell 85 are laminated on a light-transmitting insulating substrate (surface substrate) 81 in this order, furthermore, a sealing film (sealant) 86 and a back film 87 serving as a back face protective sheet for weather resistance and high insulation are laminated on the back face electrode film 84, and the whole is lamination-sealed.

As the light-transmitting insulating substrate 81, a heat resistant resin can be used such as glass or polyimide. As the transparent electrode film 82, SnO₂, ZnO, ITO or the like can be used. As the photoelectric conversion layer 83, a silicon-based photoelectric conversion film such as amorphous silicon or microcrystalline silicon, or a compound-based photoelectric conversion film such as CdTe or CuInSe₂ can be used. The back face electrode film 84 can be made of, for example, a ZnO transparent conductive film and a thin silver film. Furthermore, as the sealing film 86, a thermoplastic polymer film is preferably used, and particularly it is optimal to use a thermoplastic polymer film made of EVA (ethylene vinyl acetate resin) or PVB (polyvinyl butyral resin). Furthermore, the back film 87 has, in order to ensure a moisture resistance, a three-layer structure of PET/Al/PET (PET: polyethylene terephthalate) or a three-layer structure of PVF/Al/PVF (PVF: polyvinyl fluoride resin film). In other words, PET or PVF alone cannot prevent water vapor from entering although it can prevent attached water droplets from entering, and therefore an Al layer which is a conductive metal layer (waterproof layer) capable of preventing water vapor from entering is incorporated in the film.

It is desirable to reduce the weight of the solar cell module 1 thus configured as much as possible from the viewpoint of reducing transportation cost as well as support loads in the installation location. For this reason, it is preferable that the solar cell module 1 is made of a lightweight material such as aluminum, and the longer side frame members 10 and the shorter side frame members 20, as well as a reinforcement frame member and the like which will be described later, are made of aluminum having conductivity. In other words, they can be molded by extruding aluminum. They may be made of titanium, stainless steel or an aluminum alloy such as duralumin.

One of the shorter side frame members 20 holds an edge of the solar cell panel 2 that is positioned on the ridge side of a house, and the other shorter side frame member 20 of the solar cell module holds an edge of the solar cell panel 2 that is positioned on the eaves side of the house. The longer side frame members 10 hold right and left longer side edge portions of the solar cell panel 2, and are coupled to the edges of the shorter side frame members 20.

A basic configuration of the longer side frame member 10 and the shorter side frame member 20 will be described next by referring mainly to FIGS. 4 and 5. In the following description regarding the cross-sectional shape, in FIG. 4, the right side of the longer side frame member 10 and the shorter side frame member 20 will be referred to as outside constituting the outer periphery of the solar cell panel 2, and the left side of the longer side frame member 10 and the shorter side frame member 20 will be referred to as inside, or in other words, the side that supports the solar cell panel 2. FIGS. 4 and 5 show views as viewed from the back face of the solar cell module (the side opposite to the light-receiving face).

Description of Longer Side Frame Member 10

As shown in FIG. 4, the longer side frame member 10 is formed in a frame shape having a rectangular closed cross section (internal space 10a) composed of a longer side outer wall 11, a longer side upper wall 12, a longer side inner wall 13 and a longer side lower wall 14, and includes a bent extension piece 15 that upwardly extends from the longer side outer wall 11 and is bent inwardly (toward the right in the diagram). Accordingly, a groove portion 16 into which the outer peripheral edge of the solar cell panel 2 is fitted is formed between the longer side upper wall 12 and a horizontal portion 15b of the bent extension piece 15 in the longer side frame member 10. The groove portion 16 has a width dimension (the dimension in the vertical direction of FIG. 4) set to be slightly greater than a thickness dimension (the dimension in the vertical direction of FIG. 6) of the solar cell panel 2.

A fixing rib piece 17 having screw holes 17a for fixing/attachment of a reinforcement member 30, which will be described later, with screws or the like is formed in a lower portion of the longer side inner wall 13 of the longer side frame member 10. The fixing rib piece 17 is disposed above the longer side lower wall 14 of the longer side frame member 10 by an amount corresponding to the thickness of a lower horizontal plate 32 of the reinforcement member 30, which will be described later. In other words, a height difference corresponding to the thickness of lower horizontal plate 32 of the reinforcement member 30 is formed between the longer side lower wall 14 and the fixing rib piece 17. The screw holes 17a of the fixing rib piece 17 are provided so as to correspond to the attachment position of the reinforcement the frame member 30.

A longer side weeper hole 18 elongated along the longitudinal direction of the longer side frame member 10 is formed near each end portion of the longer side inner wall 13 of the longer side frame member 10. The longer side weeper hole 18 is formed in a position apart from an end portion 13a of the longer side inner wall 13 by a predetermined distance X1 (shown in FIG. 5). The predetermined distance X1 will be described later. Furthermore, screw fitting portions 19 each having a screw hole are provided inside the longer side outer wall 11.

Description of Shorter Side Frame Member 20

The shorter side frame member 20 is formed in a frame shape having a rectangular closed cross section (internal space 27) composed of a shorter side outer wall 21, a shorter side upper wall 22, a shorter side inner wall 23 and a shorter side lower wall 24, and includes a bent extension piece 25 that upwardly extends from the shorter side outer wall 21 and is bent inwardly (toward the right in the diagram). Accordingly, a groove portion 26 into which the outer peripheral edge of the solar cell panel 2 is fitted is formed between the shorter side upper wall 22 and a horizontal portion 25b of the bent extension piece 25 in the shorter side frame member 20. The groove portion 26 has a width dimension (the dimension in the vertical direction of FIG. 4) set to be slightly greater than the thickness dimension (the dimension in the vertical direction of FIG. 6) of the solar cell panel 2.

A shorter side weeper hole 28 elongated along the longitudinal direction of the shorter side frame member 20 is formed near each end portion of the shorter side lower wall 24 of the shorter side frame member 20.

In each end portion of the shorter side frame member 20, a flat shorter side outer wall end face 21a is formed in the shorter side outer wall 21 by removing the shorter side upper wall 22, the shorter side inner wall 23, the shorter side lower wall 24 and the bent extension piece 25 from the edge of the shorter side outer wall 21 by a width equal to the width of the longer side frame member 10 (in other words, the width of the longer side upper wall 12, the longer side lower wall 14 and a horizontal portion 15a of the bent extension piece 15). Then, in the shorter side outer wall end face 21a, screw holes 29 are formed so as to correspond to the screw fitting portions 19 provided inside the longer side outer wall 11 of the longer side frame member 10.

FIG. 5 shows a state in which an end portion of the longer side frame member 10 has been abutted and coupled to the shorter side outer wall end face 21a of the shorter side frame member 20 by screwing screws 50 in the screw holes 29 and the screw fitting portions 19 from the outside. In this state, the longer side weeper hole 18 formed in the longer side inner wall 13 of the longer side frame member 10 is positioned such that a portion on the end portion side of the longer side weeper hole 18 is open within the internal space 27 of the shorter side frame member 20. In other words, the position of the longer side weeper hole 18 is determined such that the predetermined distance X1 described above is shorter than a width X2 of the internal space 27 of the shorter side frame member 20 (X1 is about one half X2 in FIG. 5). With this configuration, rain water or the like that has flowed through the longer side frame member 10 can flow into the internal space 27 of the shorter side frame member 20 through the longer side weeper hole 18 and flow out from the shorter side weeper hole 28 formed in the shorter side lower wall 24 of the shorter side frame member 20. The thick arrow shown in FIG. 5 shows a state in which water that has entered the frame member 3 is discharged to the outside. The longer side weeper hole 18 has a shape having a length of 50 mm and a width of 8 mm, and the predetermined distance is about 5 mm. The reason that the longer side weeper hole 18 is formed at a position apart from the end portion 13a of the longer side inner wall 13 by the predetermined distance X1 is to maintain the strength of the end portion of the longer side frame member 10 by forming the end portion of the longer side frame member 10 to have a complete frame shape.

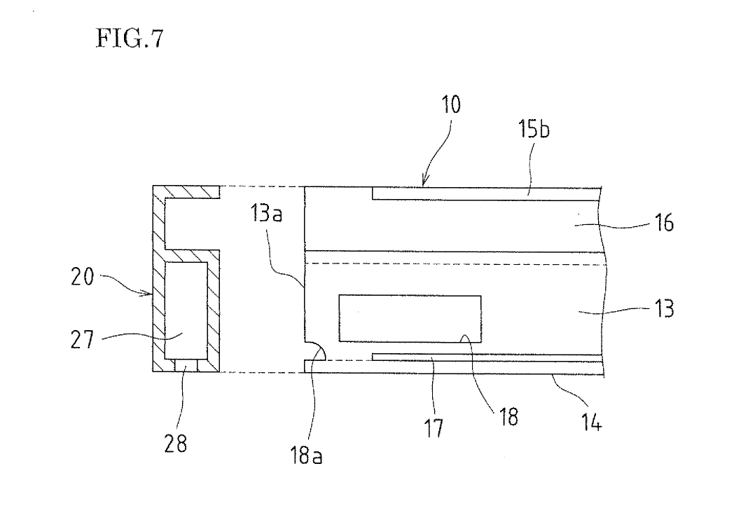

The solar cell module 1 is usually disposed in a position inclined approximately 45 to 60 degrees from the horizontal line. Accordingly, depending on the position of formation of the longer side weeper hole 18, water that has flowed through the longer side internal space 10a may accumulate in a lower angular portion of the end portion 13a of the longer side inner wall 13 to some extent. To address this, for example, as shown in FIG. 7, in addition to the longer side weeper hole 18 formed in the longer side inner wall 13, a second weeper hole 18a having an arc or triangular shape (an arc shape in FIG. 7) may be formed in the lower angular portion of the end portion 13a of the longer side inner wall 13. However, as described above, the shape of the second weeper hole 18a has a size that does not compromise the strength of the end portion of the longer side frame member 10.

Description of Reinforcement Member 30

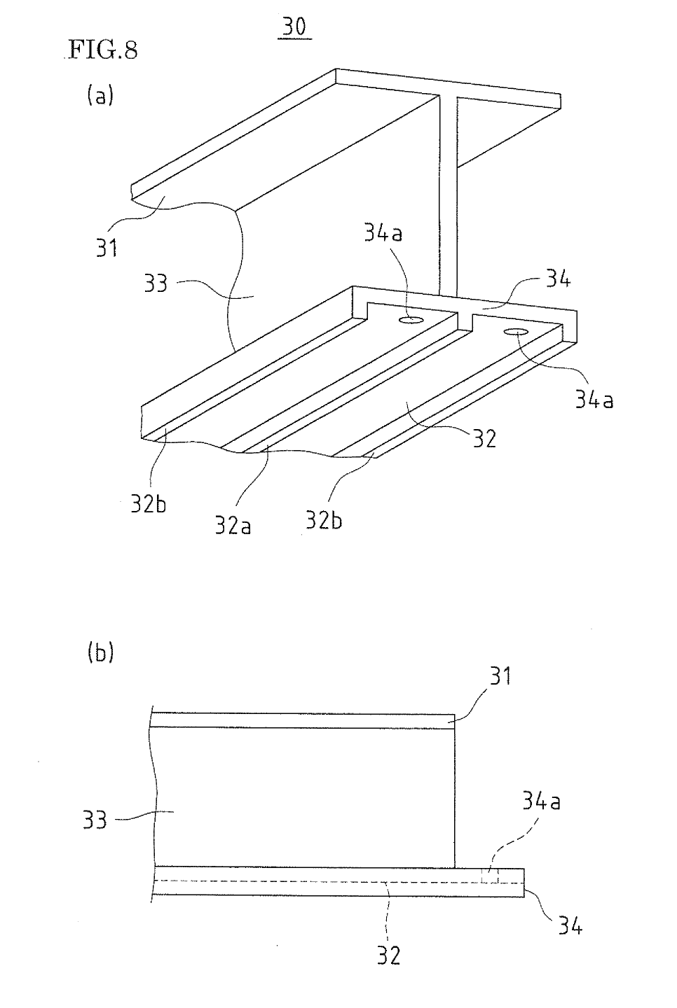

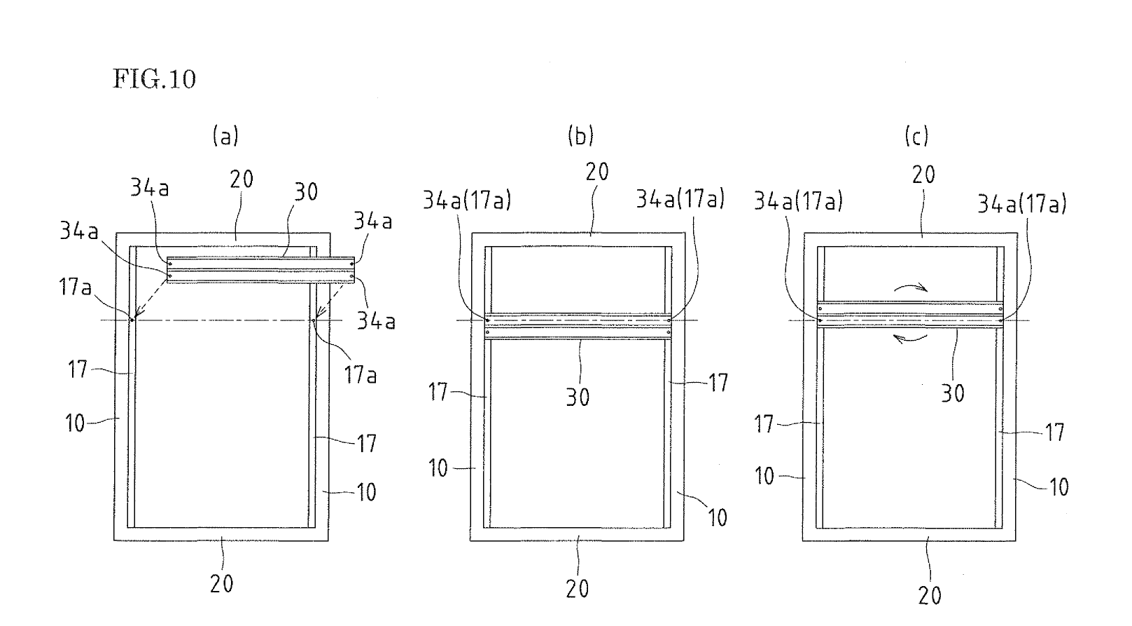

FIG. 8 is a perspective view showing the shape of a reinforcement member 30. In this example, the reinforcement member 30 has an H-shaped cross section composed of an upper horizontal plate (also referred to as “upper piece” or “upper flange”) 31, a lower horizontal plate (also referred to as “lower piece” or “lower flange”) 32 and a vertical support plate (also referred to as “support piece” or “web”) 33 that supports these horizontal plates. In each end portion of the lower horizontal plate 32 of the reinforcement member 30, a screw fixing portion 34 (the proximal rib piece is shown in FIG. 10) for being fixed to the fixing rib piece 17 of the right or left longer side frame member 10 using screws is formed.

Also, on the underside of the lower horizontal plate 32 including the screw fixing portions 34, a first reinforcing rib piece 32a having a protruding shape is formed coaxially with the vertical support plate 33 along the coupling portion coupling to the vertical support plate 33. In other words, in the reinforcement member 30, because the weight of the solar cell panel 2 is concentratedly applied to the vertical support plate 33, the first reinforcing rib piece 32a is formed in that portion so as to increase the thickness, and strength is thereby ensured.

Furthermore, in the present embodiment, second reinforcing rib pieces 32b are also formed along the longitudinal direction on both edge portions of the underside of the lower horizontal plate 32 including the screw fixing portions 34. By forming the second reinforcing rib pieces 32b, the strength of the lower horizontal plate 32 itself can be maintained. In particular, the strength of the screw fixing portions 34 can be maintained. Here, the first reinforcing rib piece 32a and the second reinforcing rib pieces 32b are formed to have a rectangular cross section, but the shape is not limited thereto, and the first reinforcing rib piece 32a and the second reinforcing rib pieces 32b may have, for example, an arc cross-sectional shape or the like.

Screw holes 34a for insertion of screws are formed in the screw fixing portions 34 formed as described above.

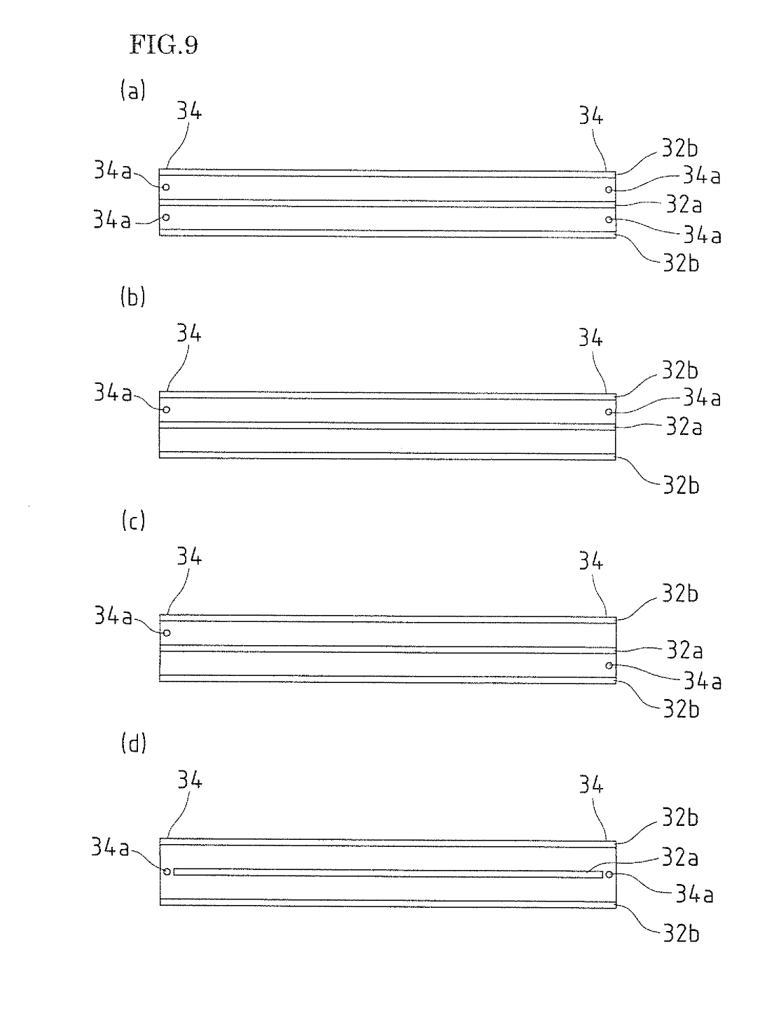

FIG. 9 show specific examples of positions of formation of screw holes 34a formed in the two screw fixing portions 34 of the reinforcement member 30. FIG. 9(a) shows an example in which screw holes 34a are formed in a recess portion between the first reinforcing rib piece 32a and one of the second reinforcing rib pieces 32b and a recess portion between the first reinforcing rib piece 32a and the other second reinforcing rib pieces 32b, or in other words, a total of four screw holes are formed, with two in each end portion of the lower horizontal plate 32. FIG. 9(b) shows an example in which screw holes 34a are formed only in a recess portion between the first reinforcing rib piece 32a and either one of the second reinforcing rib pieces 32b, or in other words, a total of two screw holes are formed, with one in each end portion on one of the sides of the lower horizontal plate 32 with the first reinforcing rib piece 32a therebetween. FIG. 9(c) shows an example in which in one of the screw fixing portions 34, one screw hole 34a is formed in a recess portion between the first reinforcing rib 32a and one of the second reinforcing rib pieces 32a, and in the other screw fixing portion 34, one screw hole 34a is formed in a recess portion between the first reinforcing rib 32a and the other second reinforcing rib piece 32a, or in other words, a total of two screw holes are formed, with one in an end portion of the lower horizontal plate 32 and the other in the other end portion in diagonal relationship with each other. FIG. 9(d) shows an example in which in each screw fixing portion 34, a screw hole 34a is formed on the first reinforcing rib piece 32a, or in other words, a total of two screw holes are formed, with one in each end portion on the first reinforcing rib piece 32a of the lower horizontal plate 32. In the specific example of FIG. 9(a), a sufficient strength can be obtained because there are four screw fixation points. On the other hand, even in the case of two fixation points with one in the right and the other in the left as shown in FIGS. 9(b) to 9(d), the attachment strength of the reinforcement member 30 that supports the solar cell panel 2 from below is sufficient. Accordingly, the configurations shown in FIGS. 9(b) to 9(d) with less screw attachment points are superior in terms of workability for assembly.

As for the screw holes 17a formed in the fixing rib pieces 17 of the longer side frame members 10, even if there are only a total of two screw holes 34a in the reinforcement member 30 as shown in FIGS. 9(b) to 9(d), four screw holes 17a can be provided so as to cope with the case of FIG. 9(a) having four screw holes. With this configuration, even a reinforcement member 30 having two screw holes as shown in FIGS. 9(b) to 9(d) can be attached. However, forming unused screw holes 17a in the fixing rib pieces 17 of the longer side frame members 10 may result in waste of processing. Accordingly, basically, it may be advisable to form screw holes 17a in the fixing rib pieces 17 so as to correspond to the attachment positions of the screw holes 34a formed in the reinforcement member 30.

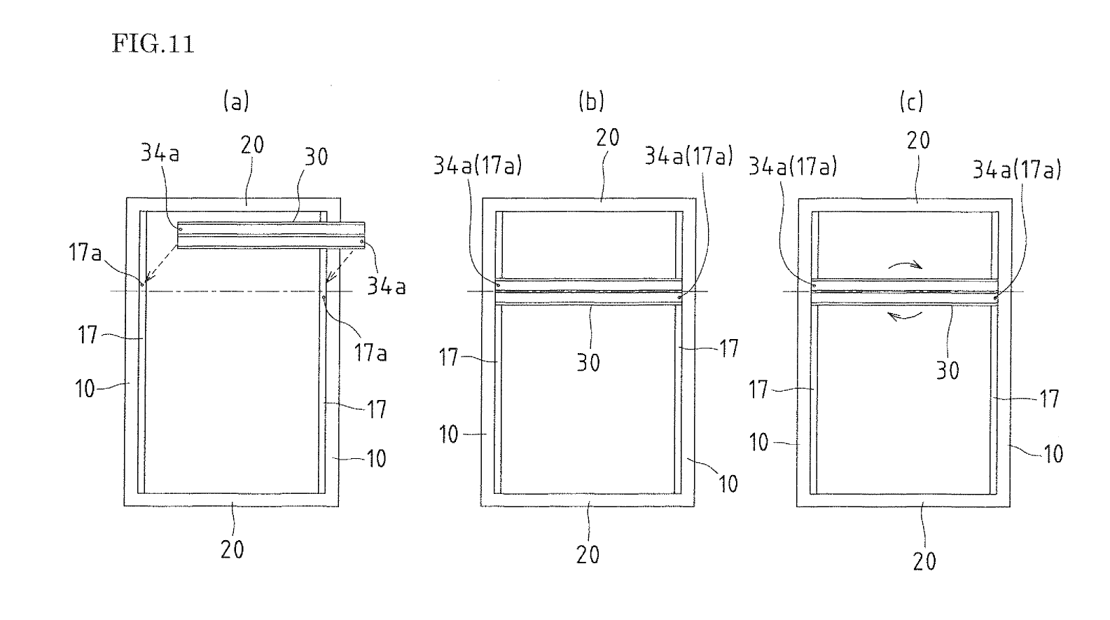

In the case where screw holes 34a have been formed on only one side of the lower horizontal plate 32 as shown in FIG. 9(b), when the screw holes 34a formed in the screw fixing portions 34 of the lower horizontal plate 32 are aligned with the screw holes 17a formed in the fixing rib pieces 17 of the longer side frame members 10, if the longer sides of the reinforcement member 30 are turned upside down (in other words, if the reinforcement member 30 is attached with a 180 degrees rotation in the horizontal direction), as shown in FIG. 10, the screw holes 17a and 34a can match at the right and left end portions. Accordingly, a selection can be made from among two attachment positions: an attachment position as shown in FIG. 10(b) and an attachment position as shown in FIG. 10(c) (an attachment position slightly shifted to a shorter side frame member 20), but there is a possibility that depending on the operator, the reinforcement member 30 might be attached in a wrong position (for example, the reinforcement member 30 might be attached as shown in FIG. 10(c) when the attachment position shown in FIG. 10(b) is the correct position). In contrast, in the case where screw holes 34a have been diagonally formed as shown in FIG. 9(c), if the longer sides of the reinforcement member 30 are turned upside down (in other words, if the reinforcement member 30 is attached with a 180 degrees rotation in the horizontal direction), as shown in FIG. 11, the screw holes 17a and 34a can match at the right and left end portions and the reinforcement member 30 can be attached to the same position (see FIGS. 11(b) and 11(c)), and therefore the reinforcement member 30 will not be attached in a wrong position.

Description of Assembly Process of Solar Cell Module 1

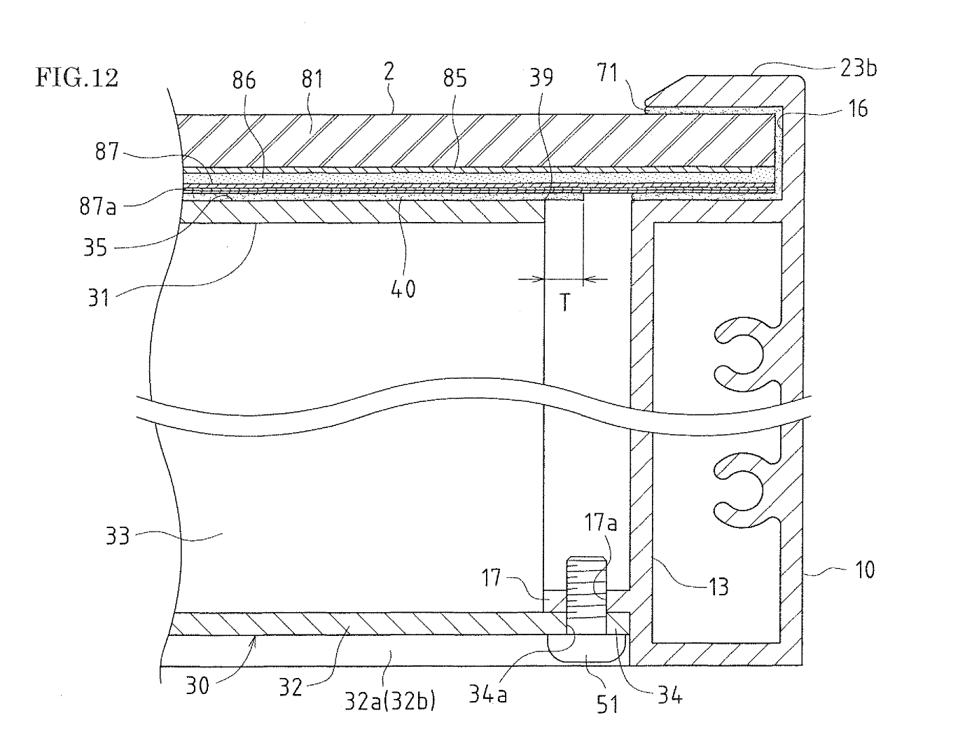

A procedure for assembling a solar cell module 1 using the members configured as described above will be described next with reference to FIG. 12.

First, an end face sealing member 71 is fitted to the peripheral edge portion of a solar cell panel 2. The end face sealing member 71 has a frame shape formed so as to conform to the outer shape of the peripheral edge portion of the solar cell panel 2, and is made of, for example, elastomer resin. Then, the groove portion 16 of each longer side frame member 10 and the groove portion 26 of each shorter side frame member 20 are fitted to the peripheral end portion of the solar cell panel 2 to which the end face sealing member 71 has been fitted (only the groove portion 16 of one longer side frame member 10 is shown in FIG. 12, and the groove portions 26 of the shorter side frame members 20 are not shown). The screw holes 29 formed in the shorter side outer wall end face 21a of the shorter side frame member 20 are then brought against the screw holes 19 formed in the longer side frame member 10 (see FIG. 4), and screws 50 are screwed into the holes, whereby the longer side frame member 10 and the shorter side frame member 20 are unitarily screw fixed.

Next, in this state, two reinforcement members 30 are disposed, from the back face of the solar cell panel 2, so as to be parallel and spaced apart with a predetermined spacing therebetween. At this time, a sticky adhesive member 40 has already been disposed on the upper surface 35 of the upper horizontal plate 31 of each reinforcement member 30 as an adhesive layer. Then, the screw fixing portion 34 formed in each end portion of the lower horizontal plate 32 of each reinforcement member 30 is placed on the fixing rib piece 17 of the right or left longer side frame member 10. Screws 51 are inserted from the screw holes 34a formed in the screw fixing portion 34 of the reinforcement member 30 and screwed into the screw holes 17a of the fixing rib piece 17 of the right or left longer side frame member 10. The reinforcement member 30 is thereby fixed to the right and left longer side frame members 10. At this time, the elevation of the fixing rib piece 17 formed on the longer side inner wall 13 is set such that the elevation of the first and second reinforcing rib pieces 32a and 32b formed on the lower horizontal plate 32 of the reinforcement member 30 is substantially the same as the elevation of the longer side lower wall 14 of the longer side frame member 10. The height of the first and second reinforcing rib pieces 32a and 32b is set such that the head of a fixed screw 51 does not protrude from the first and second reinforcing rib pieces 32a and 32b. Accordingly, troubles will not occur during installation operation of the solar cell module 1 to the roof or the like, such as the first and second reinforcing rib pieces 32a and 32b formed on the lower horizontal plate 32 of the reinforcement member 30 or the head of a fixed screw 51 gets caught during the operation.

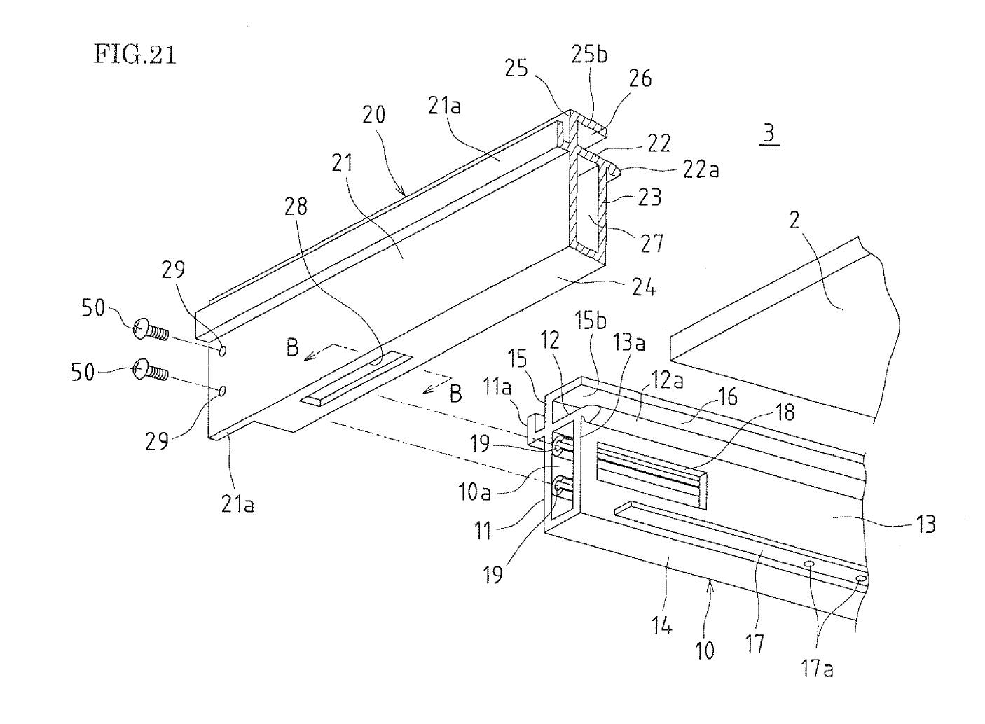

The assembly structure of the solar cell module 1 is the same as that of the conventional solar cell module shown in FIG. 21, but in the present embodiment, the shape of the adhesive member 40 that bonds the upper horizontal plate 31 of the reinforcement member 30 and the back face of the solar cell panel 2 as well as the shape of the upper horizontal plate 31 are configured so as to prevent an electrical surface discharge between the reinforcement member 30 and the Al layer of the back film 87 of the solar cell panel 2. Hereinafter, specific examples of such a configuration will be described.

### SPECIFIC EXAMPLE 1

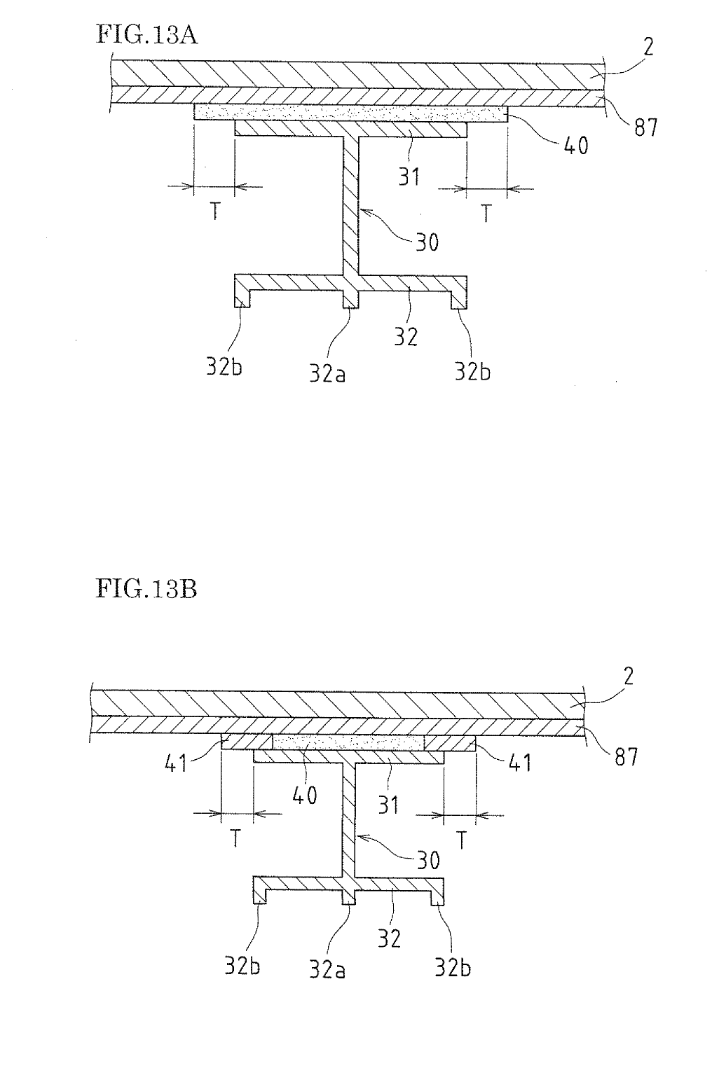

FIG. 13A shows Specific Example 1. Specifically, the adhesive member 40 serving as an adhesive layer is provided so as to protrude from the peripheral edge portion of the upper horizontal plate 31 of the reinforcement member 30 (see also FIG. 12). By providing the adhesive member 40 so as to protrude, the distance between the peripheral edge portion of the upper horizontal plate 31 of the reinforcement member 30 and the back film 87 can be increased and maintained. It is thereby possible to increase insulation between the reinforcement member 30 and the Al layer of the back film 87.

Various experiments were conducted for a length T for which the adhesive member 40 is protruded from the edge portion of the upper horizontal plate 31 of the reinforcement member 30. Here, a voltage endurance test by application of a voltage of 8 kV was conducted using at least four different protruding lengths of 0 mm, 1 mm, 2 mm and 3 mm. As a result, a sufficient effect was not obtained with a protruding length of 0 mm. The effect of preventing an electrical discharge was observed with a protruding length of 1 mm, and the effect of a preventing electrical discharge was sufficient with a protruding length of 2 mm or more, from which it can be seen that the length T for which the adhesive member 40 is protruded from the edge portion of the upper horizontal plate 31 of the reinforcement member 30 is preferably at least 2 mm. It is more preferable that the length T is at least 3 mm.

As the adhesive member 40 used in the present embodiment, other than a sticky adhesive such as silicone resin or epoxy resin, a tape-like adhesive member such as a double sided tape having two adhesive sides may be used. As the double-sided tape, it is suitable to use, for example, a tape in which an acrylic resin-based, epoxy resin-based, rubber-based or silicone resin-based sticky agent has been applied to a substrate.

When a double-sided tape is used as the adhesive member 40, the double-sided tape is formed to have a width larger than the width of the upper horizontal plate 31 of the reinforcement member 30 by an amount corresponding to 2×T. Then, the double-sided tape is applied to a predetermined position in the underside of the back film 87 so as to, for example, protrude by an amount corresponding to the length T on each side of the upper surface of the upper horizontal plate 31. The other release liner is removed, and in that state, the upper surface of the upper horizontal plate 31 is adhesively laminated to a predetermined position in the underside of the back film 87 of the solar cell panel 2. Next, the protruding portion of the double-sided tape is pressed against the back film 87 such that the protruding portion is completely bonded to the back film 87.

In this case, in order to prevent unwanted conductive matter or the like from being attached to the protruding portion of the double-sided tape, the protruding portion is made non-sticky. As a method for making the protruding portion non-sticky, for example, the surface of a portion that is to be protruded and exposed may be processed to be non-sticky when the double-sided tape is produced. It is also possible to use a method in which after a double-sided tape has been bonded in the manner described above, an insulation member such as an insulation sheet or insulation tape is applied to the surface of the protruding portion so as to make the protruding portion non-sticky. Furthermore, it is also possible to use a method in which after a double-sided tape has been bonded, the protruding portion of the double-sided tape is covered with silicone resin so as to make the protruding portion non-sticky.

Alternatively, as shown in FIG. 13B, the adhesive layer may be configured to include an adhesive member 40 and an insulation member 41. In this adhesive layer, the adhesive member 40 is provided inside in the width direction of the adhesive layer, and the insulation member 41 is attached to each edge portion of the adhesive member 40. In this case, a double-sided tape serving as the adhesive member 40 is formed to have a width smaller than the width of the upper horizontal plate 31 of the reinforcement member 30. Then, the double-sided tape is applied to a predetermined position in the underside of the back film 87, and strip-shaped insulation members 41 are attached on both sides so as to conform to the edges in the longitudinal direction of the double-sided tape. The total width of the double-sided tape and the two insulation members 41 attached is set to a width larger than the width of the upper horizontal plate 31 of the reinforcement member 30 by an amount corresponding to 2×T. As shown in FIG. 13B, each insulation member 41 is attached such that the protruding portion protrudes from an edge portion of the upper horizontal plate 31 of the reinforcement member 30 by an amount corresponding to the length T.

The insulation members 41 are adhesively fixed to the back film 87 using an adhesive. As the insulation members 41, an insulation sheet or insulation tape can be used, for example. The insulation members 41 are formed to have a thickness less than or equal to the thickness of the adhesive member 40 which can be a double-sided tape or the like, whereby when the back film 87 and the reinforcement member 30 are bonded, the adhesive member 40 can be tightly disposed between the back film 87 and the reinforcement member 30, increasing the insulation properties while increasing the adhesion properties.

Alternatively, as shown in FIG. 13C, the adhesive layer may be configured such that a double-sided tape serving as the adhesive member 40 having a width equal to the width of the upper horizontal plate 31 of the reinforcement member 30 is provided so as to overlap insulation members 41. In this case as well, the insulation members 41 are attached so as to each protrude from an edge portion of the upper horizontal plate 31 of the reinforcement member 30 by an amount corresponding to the length T.

In the configuration shown in the diagram, the insulation members 41 are provided on the underside of the back film 87 and adhesively fixed by the inner edge portions of the insulation members 41 being covered by the double-sided tape from below. In this case, for example, the insulation members 41 may be bonded in advance to two end portions of a double-sided tape that is applied to the underside of the back film 87, and the double-sided tape and the insulation members 41 may be applied to a predetermined position in the underside of the back film 87.

Next, the opposite release liner of the double-sided tape is removed, and in that state, the upper surface of the upper horizontal plate 31 is adhesively laminated such that each insulation member 41 protrudes by an amount corresponding to the length T on each side of the upper surface of the upper horizontal plate 31, and the reinforcement member 30 is installed in a predetermined position in the underside of the back film 87 of the solar cell panel 2. After that, the upper horizontal plate 31 of the reinforcement member 30 is pressed against the back film 87, and thereby the double-sided tape and the insulation members 41 are completely bonded to the back film 87.

As described above, by providing the adhesive member 40 or insulation member 41 of the adhesive layer so as to protrude from an end portion of the upper horizontal plate 31, the distance between the peripheral edge portion of the upper horizontal plate 31 of the reinforcement member 30 and the back film 87 can be increased and maintained. It is thereby possible to increase insulation between the reinforcement member 30 and the Al layer of the back film 87.

In the case where an adhesive such as silicone resin or epoxy resin is used as the adhesive member 40, the adhesive is applied to the entire upper surface of the upper horizontal plate 31 of the reinforcement member 30, and the adhesive is also applied to the back film 87 side. At this time, the adhesive applied to the back film 87 side is applied over a width greater than the width of the upper horizontal plate 31 of the reinforcement member 30 by an amount corresponding to 2×T, whereby when the upper horizontal plate 31 of the reinforcement member 30 is bonded to the back film 87, the adhesive will be bonded to the back film 87 in a state protruding from the right and left peripheral edge portions of the upper horizontal plate 31 by an amount corresponding to the length T.

As another embodiment, it may be possible that an adhesive is applied to the entire upper surface of the upper horizontal plate 31 of the reinforcement member 30, the upper surface is bonded to the back film 87, and the reinforcement member 30 is screwed and fixed to the longer side frame members 10, after which an adhesive is applied to each edge portion of the upper horizontal plate 31 of the reinforcement member 30 over a width corresponding to the length T. In this case, if it is difficult to apply an adhesive over a width corresponding to T, in each edge portion, a double-sided tape having a width corresponding to T may be applied to the back film 87.

In this case as well where a protruding portion having a width corresponding to T is formed by application of an adhesive, the protruding portion is made non-sticky in order to prevent unwanted conductive matter or the like from being attached to the protruding portion. As a method for making the protruding portion non-sticky, a method can be used in which an insulation member such as an insulation sheet or insulation tape is applied to the surface of the protruding portion so as to make the surface non-sticky.

### SPECIFIC EXAMPLE 2

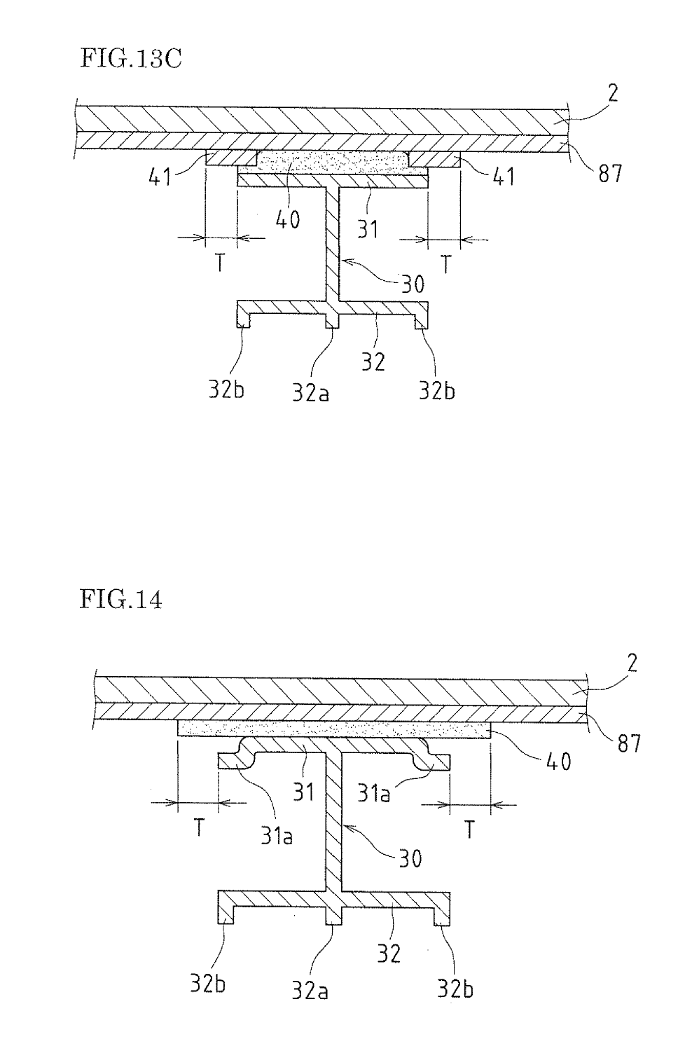

FIG. 14 shows Specific Example 2. Specifically, in Specific Example 2, the adhesive member 40 is provided so as to protrude from the peripheral edge portion of the upper horizontal plate 31 of the reinforcement member 30 as in Specific Example 1 described above, and in addition thereto, right and left side edge portions 31a of the upper horizontal plate 31 are bent downward to form a step and separated from the back film 87. In Specific Example 2, by providing the adhesive member 40 so as to protrude in the manner described above, the distance (mainly, the distance in the lateral direction) between the edge portion 31a of the upper horizontal plate 31 of the reinforcement member 30 and the back film 87 can be increased and maintained, and by downwardly bending the side edge portions 31a of the upper horizontal plate 31 of the reinforcement member 30, the distance in the height direction can also be increased and maintained. It is thereby possible to further increase insulation between the reinforcement member 30 and the Al layer of the back film 87.

Similar to Specific Example 1, in Specific Example 2, the protruding portion of the adhesive member 40 (including the bent step portion whose surface is exposed) is also made non-sticky.

### SPECIFIC EXAMPLE 3

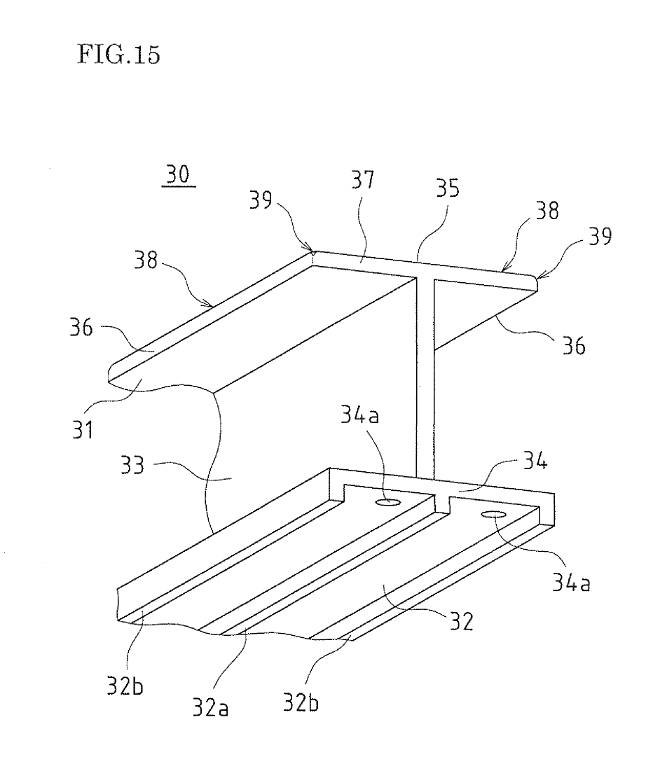

FIGS. 15 to 17 show Specific Example 3.

In the description of the process for assembling a solar cell module 1 given above, the reinforcement member 30 is fixed to the frame member 3 by inserting screws 50 from the screw holes 34a formed in the screw fixing portions 34 of the reinforcement member 30 and screwing the screws into the screw holes 17a of the fixing rib pieces 17 formed in the right and left longer side frame members 10. In this connection, Specific Example 3 is configured such that, by bonding pressure when the reinforcement member 30 is bonded to the back film 87 of the solar cell panel 2 and screwing pressure applied thereafter, a sticky adhesive serving as the adhesive member 40 is caused to flow into the angular portion of the upper surface 35 of the upper horizontal plate 31, rises up and conforms to the corner side face, and the entire angular portion is covered by the adhesive. Accordingly, in Specific Example 3, the shape of the angular portions of the upper surface 35 of the upper horizontal plate 31 of the reinforcement member 30 is distinctive.

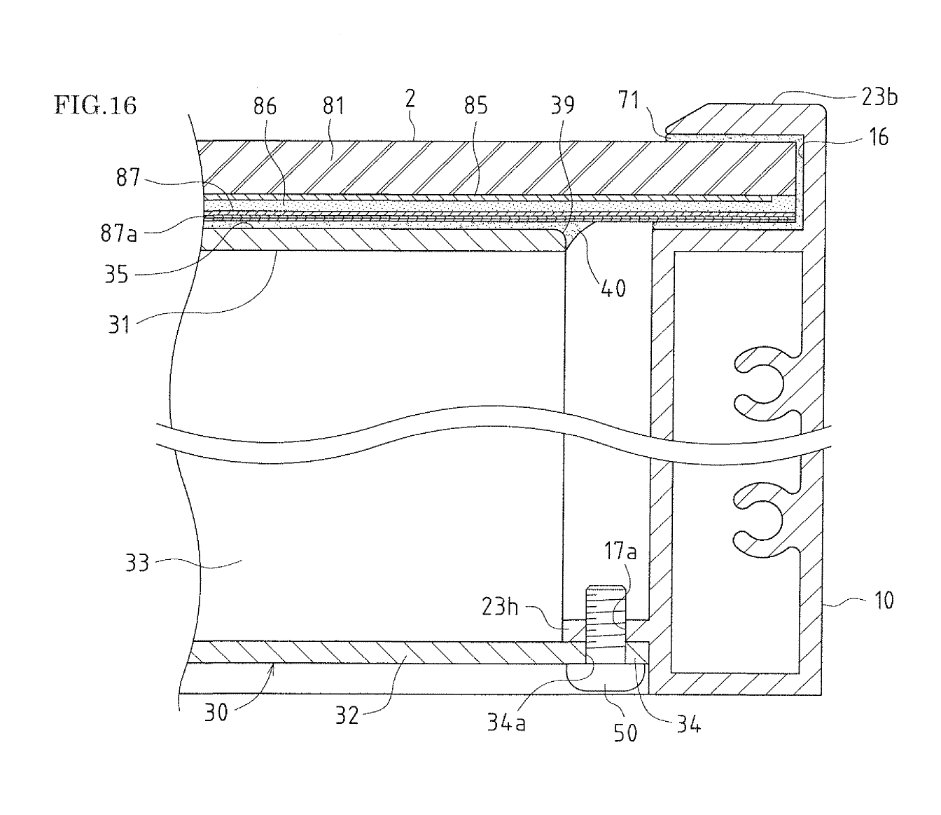

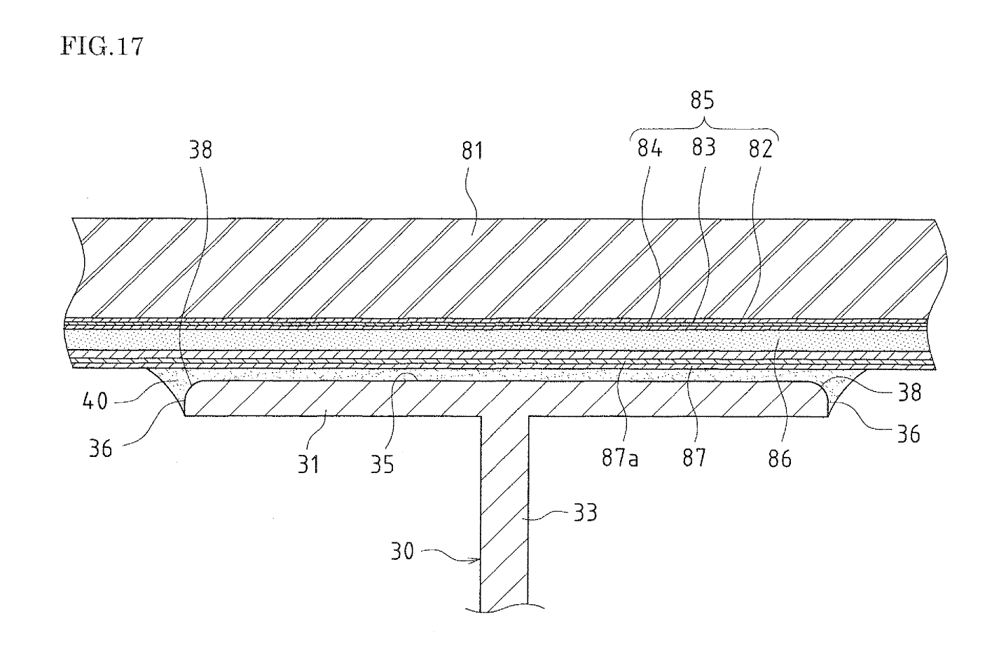

Specifically, as shown in FIGS. 15 to 17, in the reinforcement member 30 of Specific Example 3, an angular portion 39 (see FIGS. 16 and 17) formed by two faces, the upper surface 35 of the upper horizontal plate 31 that faces the back film 87 of the solar cell panel 2 and a long side face 36 or short side face 37, is formed into a round shape. An angular portion 39 (see FIG. 15) formed by three faces, the upper surface 35 of the upper horizontal plate 31 of the reinforcement member 30 and two adjacent side faces (the long side face 36 and the short side face 37), is also formed in a chamfered shape. More specifically, each angular portion 38, 39 is rounded off (this chamfered shape will be referred to as Specific Example 3-1).

Because the angular portions 38 and 39 formed by the upper surface 35 of the upper horizontal plate 31 of the reinforcement member 30 and the long side faces 36 and the short side faces 37 are chamfered, the angular portions 38 and 39 have no sharpened portions. It is thereby possible to increase insulation between the reinforcement member 30 and the Al layer 87a, which is a metal layer, of the back film 87.

In Specific Example 3, the rounded angular portions 38 and 39, as well as the long side faces 36 and the short side faces 37 are covered by an adhesive (adhesive member) 40. By covering the rounded angular portions 38 and 39 with an adhesive 40 having an insulation function such as silicone resin or epoxy resin, insulation between the reinforcement member 30 and the Al layer 87a of the back film 87 can be further increased.

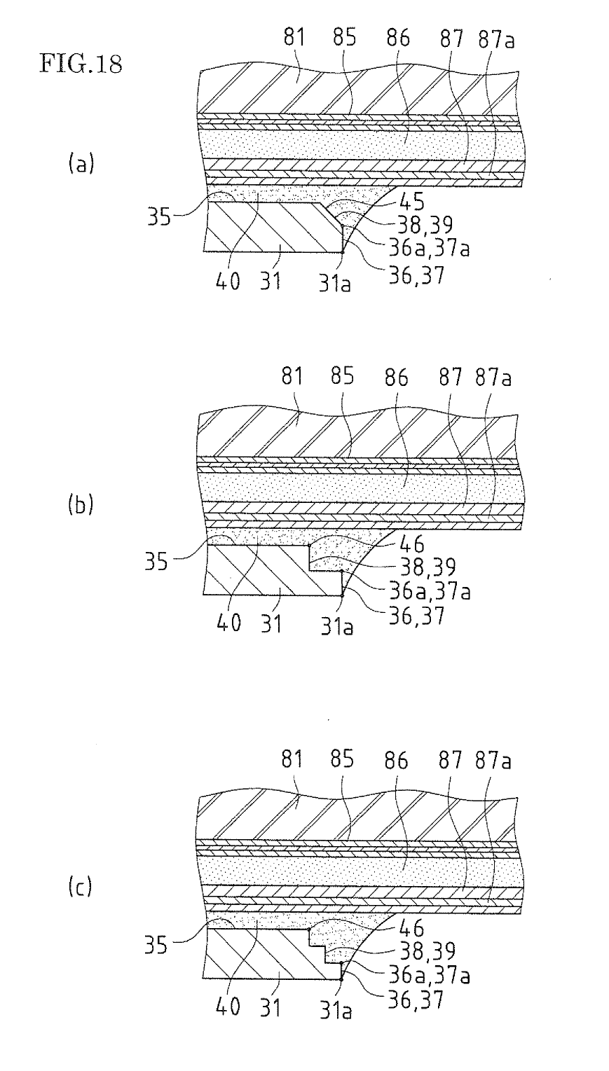

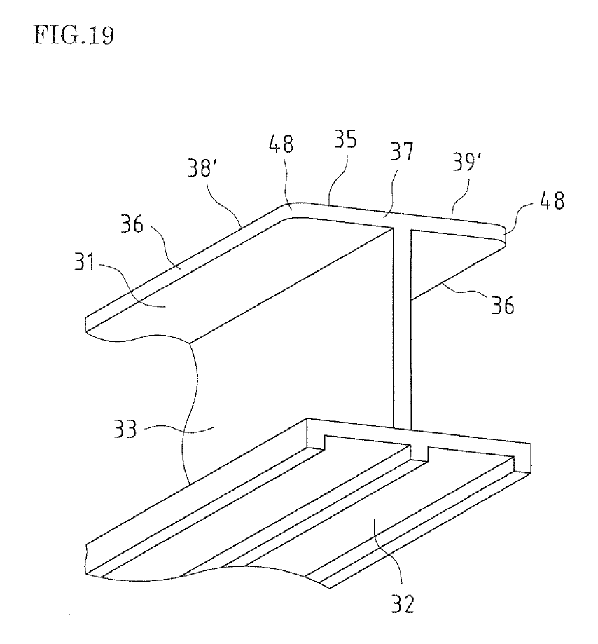

FIGS. 18 and 19 show other specific examples of the chamfered shape of the angular portions 38 and 39 of the reinforcement member 30. FIG. 18(a) shows an example in which the angular portion has been obliquely chamfered (this will be referred to as Specific Example 3-2). FIG. 18(b) shows an example in which the angular portion has been chamfered in a step shape having one step (this will be referred to as Specific Example 3-3). FIG. 18(c) shows an example in which the angular portion has been chamfered to a step shape having two steps (this will be referred to as Specific Example 3-4). FIG. 19 shows an example in which an angular portion formed by side faces 36 and 37 extending vertically from the upper surface 35 of the upper horizontal plate 31 of the reinforcement member 30 has been chamfered in a polygonal or arc shape having an angle greater than 90 degrees (this will be referred to as Specific Example 3-5).

### SPECIFIC EXAMPLE 3-2

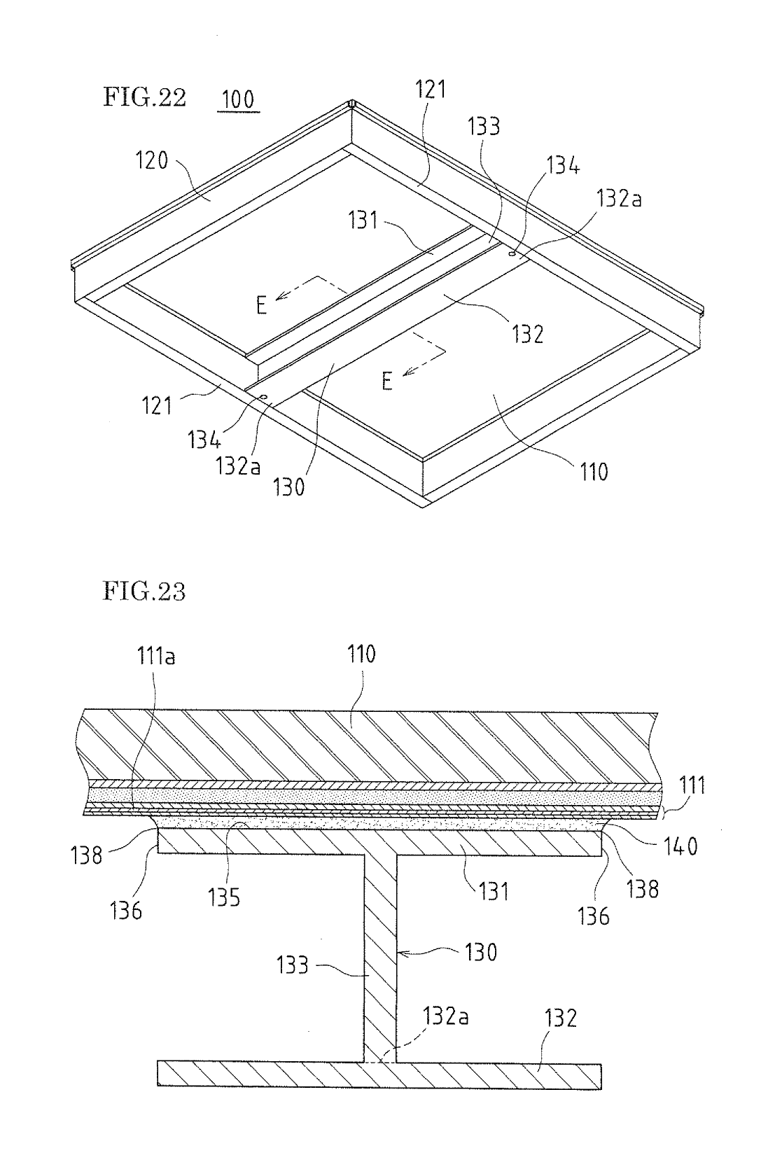

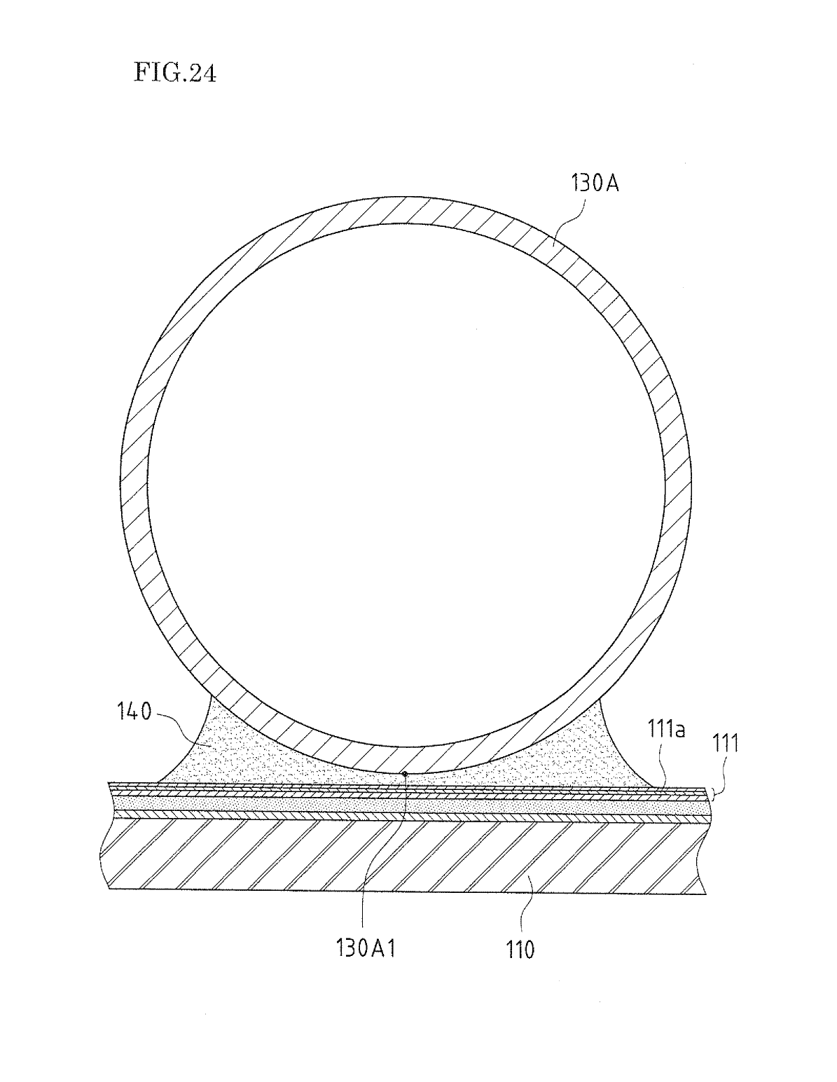

In FIG. 18(a), the angular portion 38, 39 of the reinforcement member 30 has been chamfered obliquely by cutting off the corner obliquely from a side face portion 36a, 37a slightly above a lower angular portion 31a of the upper horizontal plate 31 of the reinforcement member 30 toward the upper surface 35. In the case of cutting off the corner obliquely, an upper angular portion of the obliquely chamfered face 45, or in other words, an angular portion is formed in a position where the obliquely chamfered face 45 and the upper surface 35 are adjacent. This angular portion has an angle of about 135 degrees, which is greater than the angle (90 degrees) of the angular portion of the reinforcement member 133 of the conventional solar cell module shown in FIG. 22. Therefore, the risk of an electrical discharge is reduced accordingly. Also, a similar angular portion is formed in a position where the obliquely chamfered face 45 and the side face 36, 37 are adjacent. This angular portion is in a position separated from the back film 87 by an amount corresponding to the amount that has been obliquely chamfered, and thus the risk of an electrical discharge is reduced because the distance from the back film 87 is increased. Furthermore, in Specific Example 3, the obliquely chamfered face 45, as well as the side face 36, 37 are covered by an adhesive 40, and therefore insulation between the reinforcement member 30 and the Al layer 87a of the back film 87 can be further increased.

### SPECIFIC EXAMPLE 3-3

In FIG. 18(b), the angular portion 38, 39 of the reinforcement member 30 has been chamfered to a step shape having one step by cutting off the corner from the side face portion 36a, 37a slightly above the lower angular portion 31a of the upper horizontal plate 31 of the reinforcement member 30 toward the upper surface 35. In the case of forming the corner in such a step shape, angular portions having an angle of 90 degrees are created as in the reinforcement member 130 of the conventional solar cell module shown in FIG. 22, but the second upper angular portion excluding an uppermost angular portion 46 is in a position separated from the back film 87 by an amount corresponding to the amount removed to form the step shape, and thus the risk of an electrical discharge is reduced because the distance from the back film 87 is increased. Also, the distance between the uppermost angular portion 46 and the back film 87 is the same as the distance between the angular portion of the reinforcement member 130 and the back film 111 in the conventional solar cell module shown in FIG. 22. However, although the angular portion of the reinforcement member 130 of the conventional solar cell module is free from an adhesive and thus exposed, this step-shaped angular portion is in a position inward from the side face 36, 37 of the upper horizontal plate 31 and is reliably covered by an adhesive 40, and therefore insulation between the angular portion and the back film 87 can be increased. Furthermore, in Specific Example 3, the step-shaped angular portion and the side face 36, 37 are covered by the adhesive 40, and thus insulation between the reinforcement member 30 and the Al layer 87a of the back film 87 can be further increased.

### SPECIFIC EXAMPLE 3-4

In FIG. 18(c), the angular portion 38, 39 of the reinforcement member 30 has been chamfered to a step shape having two steps by cutting off the corner from the side face portion 36a, 37a slightly above the lower angular portion 31a of the upper horizontal plate 31 of the reinforcement member 30 toward the upper surface 35. The step shape has two steps in this example, but may have three steps or more. In the case of forming the corner in such a step shape, angular portions having an angle of 90 degrees are created as in the reinforcement member 130 of the conventional solar cell module shown in FIG. 22, but angular portions other than the uppermost angular portion 46 are in positions separated from the back film 87 by an amount corresponding to the amount removed to form the step shape, and thus the risk of an electrical discharge is reduced because the distance from the back film 87 is increased. Also, the distance between the uppermost angular portion 46 and the back film 87 is the same as the distance between the angular portion of the reinforcement member 130 and the back film 111 in the conventional solar cell module shown in FIG. 22. However, although the angular portion of the reinforcement member 130 of the conventional solar cell module is free from an adhesive and thus exposed, the uppermost angular portion of the step shape is in a position inward from the side face 36, 37 of the upper horizontal plate 31 and is reliably covered by an adhesive 40, and therefore insulation between the uppermost angular portion and the back film 87 can be increased. Furthermore, in Specific Example 3, the lowermost angular portion of the step shape and the side face 36, 37 are also covered by the adhesive 40, and thus insulation between the reinforcement member 30 and the Al layer 87a of the back film 87 can be further increased.

### SPECIFIC EXAMPLE 3-5

In FIG. 19, angular portions 38′, 39′ formed by the upper surface 35 of the upper horizontal plate 31 of the reinforcement member 30 and each side face 36, 37 have not been chamfered and therefore have the right angle. Four corner portions 48, each formed by the side faces 36 and 37 extending vertically from the upper surface 35 of the upper horizontal plate 31 of the reinforcement member 30, have been chamfered in a polygonal or arc shape having an angle greater than 90 degrees (the corner portions have an arc shape in FIG. 19). In Specific Example 3-5, the angular portions 38′, 39′ formed by the upper surface 35 and each side face 36, 37 have the right angle, and thus there is still a risk of an electrical discharge in this portion. However, in a quadrangular plate, its four corners have the highest risk of an electrical discharge, and in Specific Example 3-5, by forming four corners to have a polygonal or arc shape having an angle greater than 90 degrees, the risk of an electrical discharge at this portion can be reduced. Furthermore, in Specific Example 3, the entire side faces 36, 37 including the corner portions 48 are covered by an adhesive (adhesive member 40), and thus insulation between the reinforcement member 30 and the Al layer 87a of back film 87 can be increased.

In Specific Examples 3-1 to 3-4 above, as the chamfered shape of the angular portions of the peripheral edge portion of the upper surface 35 of the upper horizontal plate 31 of the reinforcement member 30, three example chamfered shapes were used including a round shape, an oblique shape and a step shape, but the present invention is not limited to the three chamfered shapes and encompasses any shape obtained by chamfering (for example, a concave shape, a wave shape, a polygonal shape, and the like).

Also, in Specific Examples 3-1 to 3-5 above, the configuration has been described in which when the solar cell module 1 is assembled, the sticky adhesive applied to the upper surface 35 of the upper horizontal plate 31 of the reinforcement member 30 is caused to flow into the angular portion of the upper surface 35 of the upper horizontal plate 31 as well as to the corner side face by bonding pressure when the reinforcement member 30 is bonded to the back film 87 and screwing pressure applied thereafter. However, a sticky adhesive 40 may be applied in advance so as to cover the upper surface 35 of the upper horizontal plate 31 and the side faces 36, 37 when the sticky adhesive 40 is applied to the upper surface 35 of the upper horizontal plate 31 of the reinforcement member 30 using an adhesive ejection apparatus.

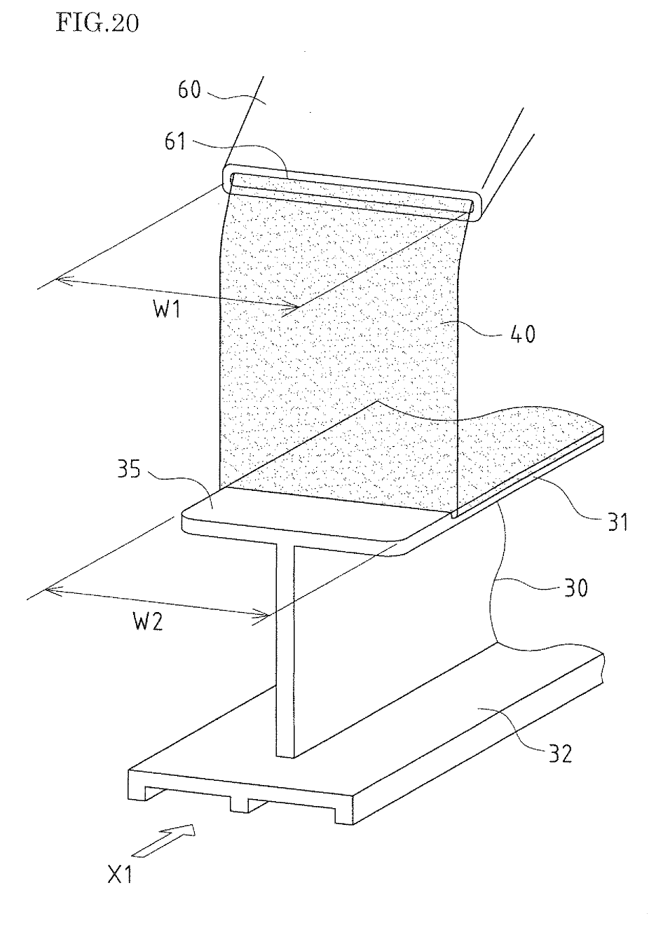

Specifically, as shown in FIG. 20, a length W1 in the longitudinal direction (the width direction of the reinforcement member 30) of a resin ejection port 61 of an adhesive ejection apparatus 60 is set to be greater than a width W2 of the upper horizontal plate 31 of the reinforcement member 30 by a predetermined length (W1>W2). Then, when the upper surface 35 of the upper horizontal plate 31 of the reinforcement member 30, facing upward, is passed in a direction indicated by X1 in the diagram under the resin ejection port 61 of the adhesive ejection apparatus 60, for example, silicone resin serving as the adhesive 40 is ejected from the resin ejection port 61 over the width W1, and thereby the adhesive (silicone resin) can be applied so as to cover the upper surface 35 of the upper horizontal plate 31 and the side face 36, 37.

The embodiments given above have been described taking an example in which two reinforcement members 30 are arranged in parallel, but the number of reinforcement members 30 is not limited to two, and may be one, three or more according to the size of the solar cell module itself or the strength needed. As for the arrangement, rather than simply arranging reinforcement members 30 in parallel, various arrangements are possible such as a cross arrangement and a rhombic arrangement.

Also, in Specific Examples 3-1 to 3-5 above, silicone resin, epoxy resin and the like are presented as examples of the adhesive, but it is also possible to use an adhesive member including a substrate (such as a double-sided tape or the like). As the double-sided tape, a double-sided tape that is flexible in the thickness direction such as “Hyper Joint 8020” available from Nitto Denko Corporation can be used, and by using such a double-sided tape, the flowability of the adhesive can be ensured.

Furthermore, other than liquid adhesives and double-sided tape as described above, it is also possible to use, for example, a kneaded product used for water leakage repair such as a putty or paste as the adhesive member 40.

In the embodiments described above, as the basic configuration of the longer side frame member 10 and the shorter side frame member 20 that constitutes the frame member 3, the frame members configured as shown in FIG. 4 were used. There are various types of frame members of different configurations depending on the intended use, and a frame member of any configuration can be used in the above embodiments. An example frame member of another configuration is shown in FIG. 21. A frame member 3 shown in FIG. 21 includes, in addition to the basic configuration of the frame member 3 of the above embodiments, an extension piece 11a, 21a that horizontally extends slightly beyond the upper portion of the longer side outer wall 11 of the longer side frame member 10 or the upper portion of the shorter side outer wall 21 of the shorter side frame member 20 and is bent upward, and a guide piece 12a, 22a for receiving and guiding the peripheral end portion of the solar cell panel 2 to the longer side groove portion 16 or the shorter side groove portion 26, the guide piece 12a, 22a formed by being extended inwardly from the longer side upper wall 12 of the longer side frame member 10 or the shorter side upper wall 22 of the shorter side frame member 20. The guide piece 12a, 22a increases the contact area with the end face sealing member 71 fitted to the peripheral end portion of the solar cell panel 2, and thus has a function of enhancing a water prevention effect of preventing water from entering the peripheral end portion of the solar cell panel 2.

The present invention may be embodied in various other forms without departing from the gist or essential characteristics thereof. Therefore, the embodiments disclosed in the embodiments given above are to be considered in all respects as illustrative and not limiting. The scope of the invention is indicated by the appended claims rather than by the foregoing description, and all modifications or changes that come within the meaning and range of equivalency of the claims are intended to be embraced therein.

Also, this application claims priority on Japanese Patent Applications Nos. 2008-302945 and 2008-302946 filed in Japan on Nov. 27, 2008, the entire content of which is incorporated herein by reference.

### INDUSTRIAL APPLICABILITY

The present invention can be suitably used in a solar cell module in which strength is increased by providing a reinforcement member.

### DESCRIPTION OF REFERENCE NUMERALS

1 Solar Cell Module
2 Solar Cell Panel
10 Longer Side Frame Member
10a Internal Space
11 Longer Side Outer Wall
12 Longer Side Upper Wall
13 Longer Side Inner Wall
13a End Portion
14 Longer Side Lower Wall
15 Bent Extension Piece
15b Horizontal Portion
16 Groove Portion
17 Fixing Rib Piece
17a Screw Hole
18 Longer Side Weeper Hole
19 Screw Fitting Portion
20 Shorter Side Frame Member
21 Shorter Side Outer Wall
22 Shorter Side Upper Wall
23 Shorter Side Inner Wall
24 Shorter Side Lower Wall
25 Bent Extension Piece
25b Horizontal Portion
26 Groove Portion
27 Internal Space
28 Shorter Side Weeper Hole
29 Screw Hole
30 Reinforcement Member
31 Upper Horizontal Plate (Upper Piece)
32 Lower Horizontal Plate (Lower Piece)
32a First Reinforcing Rib Piece
32b Second Reinforcing Rib Piece
33 Vertical Support Plate (Support Piece)
34 Screw Fixing Portion
34a Screw Hole
35 Upper Surface
36 Long Side Face (Side Face)
37 Short Side Face (Side Face)
38, 39 Angular Portion
40 Adhesive Member
41 Insulation Member
50, 51 Screw
60 Adhesive Ejection Apparatus
61 Resin Ejection Port
81 Light-Transmitting Insulating Substrate
82 Transparent Electrode Film
83 Photoelectric Conversion Layer
84 Back Face Electrode Film
85 Solar Cell
86 Sealing Film
87 Back Film (Back Face Protective Sheet)
87a Al Layer (Metal Layer)

1. A solar cell module including a solar cell panel in which a substrate, a solar cell, a sealant and a back face protective sheet are sequentially laminated,
wherein at least one reinforcement member is bonded to the back face protective sheet via an adhesive layer, and
the adhesive layer prevents an electrical surface discharge between the reinforcement member and the back face protective sheet.

2. The solar cell module according to claim 1,
wherein the reinforcement member is disposed underneath the solar cell panel supported and fixed within a rectangular frame member and is disposed between opposing frame members, and
the reinforcement member includes an upper piece that is bonded to the back face protective sheet via the adhesive layer, a lower piece having end portions that abut bottom pieces of the frame members and a support piece that couples the upper piece and the lower piece, the lower piece including, underneath, a reinforcing rib piece along an axis direction of the reinforcement member.

3. The solar cell module according to claim 2,
wherein the adhesive layer includes an adhesive member having adhesion properties and is provided between the upper piece and the back face protective sheet.

4. The solar cell module according to claim 3,
wherein the adhesive member is provided so as to protrude from a peripheral edge portion of the upper piece.

5. The solar cell module according to claim 3,
wherein the adhesive layer further includes an insulation member having electrical insulation properties and prevents an electrical surface discharge between the reinforcement member and the back face protective sheet.

6. The solar cell module according to claim 5,
wherein in the adhesive layer, the adhesive member is provided inside in a width direction of the adhesive layer, the insulation member is attached to each side edge portion of the adhesive member, and the insulation member is provided so as to protrude from a peripheral edge portion of the upper piece.

7. The solar cell module according to claim 6,
wherein in the adhesive layer, the adhesive member is attached so as to overlap the insulation member.

8. The solar cell module according to claim 4,
wherein in the adhesive member, a surface of an exposed portion protruding from the peripheral edge portion of the reinforcement member is made non-sticky.

9. The solar cell module according to claim 6,
wherein in the insulation member, a surface of an exposed portion protruding from the peripheral edge portion of the reinforcement member is made non-sticky.

10. The solar cell module according to claim 2,
wherein the upper piece of the reinforcement member has a peripheral edge portion that is bent and separated from the adhesive layer.

11. The solar cell module according to claim 2,
wherein the reinforcing rib piece is provided to the lower piece so as to extend along a coupling portion of the support piece of the reinforcement member.

12. The solar cell module according to claim 2,
wherein the reinforcing rib piece is provided to each edge portion of the lower piece.

13. The solar cell module according to claim 2,
wherein the reinforcing rib piece is formed in a protruding shape having a thickness greater than a thickness of other portions of the support piece.

14. The solar cell module according to claim 13,
wherein a screw hole for screwing the support piece to the bottom pieces of the frame members is formed in an end portion of the lower piece.

15. The solar cell module according to claim 14,
wherein the screw hole is formed between the reinforcing rib pieces.

16. The solar cell module according to claim 14,
wherein the screw hole is formed on the reinforcing rib piece provided along the coupling portion of the support piece.

17. A solar cell module that is reinforced by bonding a solar cell panel and a conductive metallic reinforcement member using an adhesive member, the solar cell module comprising:
a means for preventing an electrical discharge generated due to a relationship between a conductive member included in the solar cell panel and the reinforcement member.

18. A solar cell module in which a solar cell panel is reinforced by a reinforcement member,
wherein the reinforcement member is provided with an anti-deformation portion that prevents deformation of the reinforcement member.

19. A solar cell module including a solar cell panel in which a substrate, a solar cell, a sealant and a back face protective sheet are sequentially laminated,
wherein at least one reinforcement member is bonded to the back face protective sheet via an adhesive layer,
the reinforcement member is disposed underneath the solar cell panel supported and fixed within a rectangular frame member and is disposed between opposing frame members,
the reinforcement member includes an upper piece that is bonded to the back face protective sheet via the adhesive layer, a lower piece having end portions that abut bottom pieces of the frame members and a support piece that couples the upper piece and the lower piece, the lower piece including, underneath, a reinforcing rib piece along an axis direction of the reinforcement member, and
the adhesive layer is formed so as to protrude from a peripheral edge portion of the upper piece and prevents an electrical surface discharge between the reinforcement member and the back face protective sheet.
